(19) United States
(12) Patent Application Publication
(10) Pub. No.: US 2009/0266418 A1
(43) Pub. Date: Oct. 29, 2009

(54) PHOTOVOLTAIC DEVICES BASED ON NANOSTRUCTURED POLYMER FILMS MOLDED FROM POROUS TEMPLATE

(75) Inventors: Wenchuang Hu, Allen, TX (US); Mukti N. Aryal, Dallas, TX (US); Fatih Buyukserin, Richardson, TX (US); Jinming Gao, Plano, TX (US); Xiao-Mei Zhao, Plano, TX (US)

Correspondence Address: CHALKER FLORES, LLP, 2711 LBJ FRWY, Suite 1036, DALLAS, TX, 75234, US

(73) Assignee: BOARD OF REGENTS, THE UNIVERSITY OF TEXAS SYSTEM, Austin, TX (US)

(21) Appl. No.: 12/388,212

(22) Filed: Feb. 18, 2009

Related U.S. Application Data
(60) Provisional application No. 61/029,508, filed on Feb. 18, 2008.

(51) Int. Cl. H01L 31/0296; H01L 31/02; H01L 31/0256; C25D 11/02; B32B 5/18; B29C 59/00

(52) U.S. Cl. 136/260; 136/252; 136/263; 136/261; 438/82; 205/171; 205/50; 264/40.1; 977/742; 977/773; 977/774; 257/E31.003

(57) ABSTRACT

The present invention includes a template, an optoelectronic device and methods for making the same. The optoelectronic device includes a first substrate; a first electrode disposed on the first substrate; a first interdigitating, nano-structured charge-transfer molded material (e.g., a polymer) with a first electron affinity disposed on the first electrode; a second interdigitating, nano-structured charge-transfer material (e.g., single molecules, quantum dots, or particles) with a second electron affinity disposed on the first interdigitating, nano-structured charge-transfer material; a second electrode disposed in the second interdigitating, nano-structured charge-transfer material; and a second substrate disposed on the second electrode.

### CROSS-REFERENCE TO RELATED APPLICATIONS

This application claims benefit of U.S. Provisional application Ser. No. 61/029,508, filed Feb. 18, 2008, which is incorporated herein by reference in its entirety.

### TECHNICAL FIELD OF THE INVENTION

The present invention relates in general to the field of photovoltaic devices, and more particularly, to nanostructured polymer films molded from a porous template.

### STATEMENT OF FEDERALLY FUNDED RESEARCH

None.

### BACKGROUND OF THE INVENTION

Without limiting the scope of the invention, its background is described in connection with organic photovoltaic cells.

U.S. Pat. Nos. 7,291,782 and 6,946,597 issued to Sager, et al., for a self-assembled optoelectronic device and fabrication method. Briefly, charge-splitting networks, optoelectronic devices, methods for making optoelectronic devices, power generation systems are disclosed. An optoelectronic device includes a porous nano-architected (e.g., surfactant-templated) film having interconnected pores that are accessible from both the underlying and overlying layers. A pore-filling material substantially fills the pores. The interconnected pores have diameters of about 1-100 nm and are distributed in a substantially uniform fashion with neighboring pores separated by a distance of about 1-100 nm. The nano-architected porous film and the pore-filling, material have complementary charge-transfer properties with respect to each other, i.e., one is an electron-acceptor and the other is a hole-acceptor. The nano-architected porous, film may be formed on a substrate by a surfactant temptation technique such as evaporation-induced self-assembly. A solar power generation system may include an array of such optoelectronic devices in the form of photovoltaic cells with one or more cells in the array having one or more porous charge-splitting networks disposed between an electron-accepting electrode and a hole-accepting electrode.

U.S. Pat. No. 7,267,859, issued to Rabin, et al., for a thick porous anodic alumina films and nanowire arrays grown on a solid substrate. Briefly, fabrication of porous anodic alumina (PAA) films on a wide variety of substrates is disclosed. The substrate includes a wafer layer and may further include an adhesion layer deposited on the wafer layer. An anodic alumina template is formed on the substrate. When a rigid substrate such as Si is used, the resulting anodic alumina film is more tractable and manipulated without danger of cracking. The substrate can be manipulated to obtain free-standing alumina templates of high optical quality and substantially flat surfaces PAA films can also be grown this way on patterned and non-planar surfaces. Under certain conditions the resulting PAA is missing the barrier layer (partially or completely) and the bottom of the pores can be readily accessed electrically. The resultant film can be used as a template for forming an array of nanowires wherein the nanowires are deposited electrochemically into the pores of the template. By patterning the electrically conducting adhesion layer, pores in different areas of the template can be addressed independently and can be filled electrochemically by different materials. Single-stage and multi-stage nanowire-based thermoelectric devices, consisting of both n-type and p-type nanowires, can be assembled on a silicon substrate by this method.

U.S. Pat. No. 5,772,905, issued to Chou is directed to nanoimprint lithography. Briefly, a lithographic method and apparatus is taught for creating ultra-fine (sub-25 nm) patterns in a thin film coated on a substrate, in which a mold having at least one protruding feature is pressed into a thin film carried on a substrate. The protruding feature in the mold creates a recess of the thin film and the mold can be removed from the film. The thin film is processed such that the thin film in the recess is removed exposing the underlying substrate. The patterns in the mold are replaced in the thin film, completing the lithography. The patterns in the thin film will be, in subsequent processes, reproduced in the substrate or in another material which is added onto the substrate.

### SUMMARY OF THE INVENTION

The present invention provides compositions and methods for making high-performance photovoltaic devices, such as solar cells, based on nanostructured charge-transfer materials. The optoelectronic device includes a nanostructured material as the first charge-transfer layer and another material with different electron affinity to fill the space of the first layer. The nanostructures in the first charge-transfer material is formed by molding the first charge-transfer material using a porous template under applied heat, pressure, and optional UV exposure. Such process creates a vertically bi-continuous and interdigitized morphology of pn heterojunctions for efficient harvesting of solar energy. This molding process may be also referred as hot-embossing, or nanoimprint lithography [1].

In another embodiment, the present invention includes an optoelectronic device, comprising: a first substrate, wherein the substrate comprises one or more active regions; an electrode disposed on the first substrate; a first interdigitating, nano-structured charge-transfer molded polymer comprising a first electron affinity disposed on the first electrode, wherein the first nano-structured polymer comprises aligned or stacked polymer chains, i.e., aligned and with higher crystallinity than the bulk material before the molding process; a second interdigitating, nano-structured charge-transfer material comprising a second electron affinity disposed on the first interdigitating, nano-structured charge-transfer material; a second electrode disposed in the second interdigitating, nano-structured charge-transfer material; and a layer disposed on the second electrode. In one aspect, at least one of the first and second nanostructured charge transfer materials are further defined as comprising vertical aligned chains for improved charge mobility. In another aspect, at least one of the first and second nanostructured materials comprise laterally aligned and vertically stacked “π-chains”, i.e., π stacking vertically for high charge mobility. In yet another aspect, the crystallinity of the molded material is greater than the crystallinity of the original un-molded bulk material before they are molded.

The porous template used in the molding process may be an anodic metal film that is prepared by electrochemically anodizing a metal film, or made of other materials by transferring nanostructures from the anodic metal film using etching or additive methods. A template based on porous anodic metal films, the replication of anodic metal films on other materials, the manufacturing process and the architecture of the photovoltaic devices and methods of manufacture are also part of the present invention.

In one embodiment, the present is an optoelectronic device having a first substrate; a first electrode disposed on the first substrate; a first interdigitating, nano-structured charge-transfer molded materials (e.g., polymer, hydrogel, monomers, etc.) that includes a first electron affinity disposed on the first electrode; a second interdigitating, nano-structured charge-transfer materials (e.g., polymer, molecules, quantum dots, hydrogel, etc.), which includes a second electron affinity disposed on the first interdigitating, nano-structured charge-transfer material; a second electrode disposed in the second interdigitating, nano-structured charge-transfer material; and a second substrate disposed on the second electrode. In one aspect, the first and second materials are an electron-acceptor: hole-acceptor pair.

Non-limiting examples of first and second materials may be are selected from poly(para-phenylenevinylene) derivatives, such as poly[2-methoxy-5-(2′-ethyl-hexyloxy)-1,4-phenylene vinylene] (MEH-PPV) or (poly-[2-(3,7-dimethyl-octyloxy)-5-methyloxy]-PPV (MDMO-PPV), poly(para-phenylenevinylene) (PPV), PPV copolymers, poly(thiophene) and derivatives, regioregular poly(3-octylthiophene-2,5,-diyl), regiorandom poly(3-octylthiophene-2,5,-diyl), poly (3-hexylthiophene) (P3HT), regioregular poly(3-hexylthiophene-2,5-diyl), regiorandom poly(3-hexylthiophene-2,5-diyl), poly(thienylenevinylene) and derivatives thereof, poly(isothianaphthene) and derivatives thereof, tetra-hydrothiophene precursors and derivatives thereof, organometallic polymers, polymers containing perylene units, poly(squaraines) and their derivatives, discotic liquid crystals, polyfluorenes, polyfluorene copolymers, polyfluorene-based copolymers and blends co-polymerized and/or blended with charge transporting and/or light absorbing compounds, tri-phenyl-amines and derivatives, fused thiophene rings and derivatives, and hetero-atom ring compounds with or without substituents, polymer systems with low bandgap, such as poly[2,6-(4,4-bis-(2-ethylhexyl)-4H-cyclopenta[2,1-b; 3,4-b′]-dithiophene)-alt-4,7-(2,1,3-benzothiadiazole)] or PCPDTBT, quantum dots, and C60 derivatives, such as 1-(3-methoxycarbonyl) propyl-1-phenyl [6,6] C61) system (PCBM), a pigment or dye chosen from the group of organic pigments or dyes, azo-dyes having azo chromofores (—N═N—) linking aromatic groups, phthalocyanines including metal-free phthalocyanine (HPc), perylenes, naphthalocyanines, squaraines, merocyanines and their respective derivatives, poly(silanes), poly(germinates), 2,9-di(pent-3-yl)-anthra[2,1,9-def: 6,5,10-d′e′f′] diisoquinoline-1,3,8,10-tetrone, and 2,9-Bis-(1-hexyl-hept-1-yl)-anthra[2,1,9-def:6,5,10-d′e′f′] diisoquinoline-1,3,8,10-tetrone, metal oxide gels (e.g., TiO₂ gel), and combinations thereof.

In another aspect, at least one of the first and second substrate is optically translucent. In another aspect, the first, the second or both the first and second substrate may be, e.g., silicon, polysilicon, glass, plastic or metal. The first or the second electrode may be made from, e.g., indium-tin-oxide (ITO) or carbon nanotubes sheets and contact the polymer layer that serves as a hole-transfer layer. In another aspect, the first or the second electrode may be, e.g., aluminum or a metal and the electrodes contact the polymer that serves as an electron-transfer layer. The first and second interdigitating nano-structured charge-transfer polymers include periodic structured nanoposts or nanopores having an average pore diameter of 10-100 nm or gratings with a width of 10-100 nm. The first and second interdigitating nano-structured charge-transfer materials may include periodic structured nanoposts, nanopores, and gratings that are separated by a range from 5-500 nm including all values between 5 and 500, for e.g., 1, 2, 3, 4, 5, 7, 10, 15, 20, 30, 40, 50, 60, 70, 80, 90, 100, 150, 200, 250 or 500 nm and incremental variations thereof on center. The first and second interdigitating nano-structured charge-transfer materials of the device may have periodic structured nanoposts, nanopores, nanogratings having an aspect ratio greater than 1. In another aspect, the first and second interdigitating nano-structured charge-transfer polymers may have periodic structured nanoposts, nanopores, or gratings with a height of 1, 2, 5, 7, 10, 20, 40, 50, 75, 100, 250, 500, 1,000, 2,000, 3,000, 4,000 and 5000 nm. The first and second interdigitating nano-structured charge-transfer material may also be defined further as being imprint-induced nano-crystallization polymers which results in higher charge mobility, and higher power output. The device may also include one or more passivation layers on the first or second substrates opposite the first and second electrodes. Extra electron and hole injection material, e.g. PEDOT:PSS/Sorbitol (Poly(3,4-ethylenedioxythiophene) poly(styrenesulfonate) may also be used between the nanostructured materials and electrodes to enhance charge transport and collection at electrodes. In addition, third functional materials, e.g. quantum dots, CdSe particles, Au particles, Ag particles may also be deposited between the nanostructured hole and electron transfer materials to enhance light absorption and charge generation.

The present invention also includes a method of making an optoelectronic device by nanoimprinting or molding a first interdigitating, nano-structured charge-transfer material with a template mold, the material comprising a base and one or more nanoposts, pores, or gratings; depositing a second charge-transfer material layer on the first interdigitating, nano-structured charge-transfer polymer to form a electron-acceptor:hole-acceptor pair, interface or pn junction; and connecting each of the first and second nano-structured charge-transfer material to an electrode, wherein at least one of the electrodes in translucent. In one aspect the second charge-transfer material is deposited on an electrode and bonded to the first charge transfer layer with the second nanoimprint process. In another aspect the second charge-transfer material is deposited on a substrate and is interditated to the first charge-transfer layer in a nanoimprint process. In a further aspect the charge-transfer materials comprise increased adhesion and electrical contact of the charge-transfer materials, by modification of the polymer chain ends with functional groups, changing the chemical coating of the particle surfaces, or using one or more solvents that improve material deposition. In one aspect, first and second material are selected from poly(para-phenylenevinylene) derivatives, such as poly[2-methoxy-5-(2′-ethyl-hexyloxy)-1,4-phenylene vinylene] (MEH-PPV) or (poly-[2-(3,7-dimethyl-octyloxy)-5-methyloxy]-PPV (MDMO-PPV), poly(para-phenylenevinylene) (PPV), PPV copolymers, poly(thiophene) and derivatives, regioregular poly(3-octylthiophene-2,5,-diyl), regiorandom poly(3-octylthiophene-2,5,-diyl), poly (3-hexylthiophene) (P3HT), regioregular poly(3-hexylthiophene-2,5-diyl), regiorandom poly(3-hexylthiophene-2,5-diyl), poly(thienylenevinylene) and derivatives thereof, poly(isothianaphthene) and derivatives thereof, tetra-hydrothiophene precursors and derivatives thereof, organometallic polymers, polymers containing perylene units, poly(squaraines) and their derivatives, discotic liquid crystals, polyfluorenes, polyfluorene copolymers, polyfluorene-based copolymers and blends co-polymerized and/or blended with charge transporting and/or light absorbing compounds, tri-phenyl-amines and derivatives, fused thiophene rings and derivatives, and hetero-atom ring compounds with or without substituents, such as poly[2,6-(4,4-bis-(2-ethylhexyl)-4H-cyclopenta[2,1-b; 3,4-b′]-dithiophene)-alt-4,7-(2,1,3-benzothiadiazole)] or PCPDTBT, quantum dots, C60 derivatives, such as 1-(3-methoxycarbonyl) propyl-1-phenyl [6,6] C61) system (PCBM), a pigment or dye chosen from the group of organic pigments or dyes, azo-dyes having azo chromofores (—N═N—) linking aromatic groups, phthalocyanines including metal-free phthalocyanine (HPc), perylenes, naphthalocyanines, squaraines, merocyanines and their respective derivatives, poly (silanes), poly(germinates), 2,9-di(pent-3-yl)-anthra[2,1,9-def: 6,5,10-d′e′f′] diisoquinoline-1,3,8,10-tetrone, and 2,9-Bis-(1-hexyl-hept-1-yl)-anthra[2,1,9-def:6,5,10-d′e′f′] diisoquinoline-1,3,8,10-tetrone, metal oxide gels (e.g., TiO₂ gel), and combinations thereof. In another aspect, at least one of the first and second substrate is optically translucent. The first, the second or both the first and second substrate may be, e.g., silicon, polysilicon, glass, plastic, or metal.

In one aspect, the first or the second electrode may be indium-tin-oxide (ITO) or carbon nanotubes sheets and contact the polymer layer that may be a hole-transfer layer. In another aspect, the first or the second electrode may be made from aluminum or a metal and contact the polymer that acts as the electron-transfer layer. In one aspect, the first and second interdigitating nano-structured charge-transfer polymers having periodic structured nanoposts/pores/gratings having a lateral dimension of 10-100 nm. In another aspect, the first and second interdigitating nano-structured charge-transfer materials have periodic structured nanoposts, pores, gratings having an aspect ratio of greater than 1. The first and second interdigitating nano-structured charge-transfer materials may also be treated to become imprint-induced nano-crystallization materials. In another aspect, the step of forming a first interdigitating, nano-structured charge-transfer material with a template mold includes coating an anodized template with a silane; and heating, UV treating or pressurizing the charge-transfer materials (e.g., polymer, molecule, gel, etc.) into nano-cavities in the template. In another aspect, one or more passivation layers may be placed on the first or second substrates opposite the first and second electrodes.

In another embodiment, the present invention includes a method of making a highly-ordered, nanopore template by a two step anodization process, a electrochemical process, to make ordered nanopores in metal, and also transferring the porous membrane into other materials as molds. First, a polished anodizable metal template is oxidized followed by dissolving the anodized template to form a pock-marked template; and re-anodizing the pock-marked template, wherein the re-anodized template comprises a plurality of cells that has an anodized barrier layer and a pore. The anodic template can be directly used as mold or free standing nanoporous anodic membranes can be further obtained from the template a voltage reduction method. The membrane is then used as a mask to etch a solid substrate using a two-step inductively coupled plasma (ICP) etching process to form nanostructrues in another material. After etching, the membrane is removed from the solid mold that is then treated with anti-adhesion perfluorodecyltrichlorosilane. In one aspect, the template comprises aluminum, titanium, zinc, magnesium, niobium or alloys thereof. Each cell of the template may have a pore with a diameter of 1, 2, 5, 7, 10, 20, 30, 40, 50, 60, 70, 80, 90, 100, 150, 200, 250 or 500, e.g., 1-500 nm. Each cell of the template may have a barrier layer with a thickness of 1, 2, 5, 7, 10, 20, 30, 40, or 50 nm. Each cell of the template may have a pore with a depth of 1, 2, 5, 7, 10, 20, 40, 50, 75, 100, 250, 500, 1,000, 2,000, 3,000, 4,000 and 5000 nm. Each cell of the template may have pores that are separated by 1, 2, 5, 7, 10, 20, 30, 40, 50, 60, 70, 80, 90, 100, 150, 200, 250 or 500 nm on center. In another embodiment, the present invention also includes a template made by the method as taught hereinabove.

The present invention also describes a method of orienting a polymer chain in a polymer by nanoimprinting comprising the steps of: (i) selecting the polymer for nanoimprinting; (ii) spreading the polymer as a layer for nanoimprinting; (iii) adjusting a temperature of the polymer layer; wherein said temperature is around or above the glass transition temperature of the selected polymer; (iv) adjusting a viscosity of the polymer layer; (v) contacting the polymer layer with a nanostructured mold, wherein said mold comprises one or more nano-structures; (vi) flowing the polymer into the porous mold; (vii) releasing the porous mold from the polymer layer; and monitoring the orientation of the polymer chains by one or more analytical techniques, comprising X-ray diffraction, X-ray scattering, atomic force microscopy, high resolution tunneling electron microscopy, scanning electron microscopy and combinations thereof. In one aspect the polymer chain is aligned vertically. In another aspect the π stacking of the polymer is aligned vertically.

In one aspect the polymer for nanoimprinting is selected from poly(para-phenylenevinylene) derivatives, such as poly[2-methoxy-5-(2′-ethyl-hexyloxy)-1,4-phenylene vinylene] (MEH-PPV) or (poly-[2-(3,7-dimethyl-octyloxy)-5-methyloxy]-PPV (MDMO-PPV), poly(para-phenylenevinylene) (PPV), PPV copolymers, poly(thiophene) and derivatives, regioregular poly(3-octylthiophene-2,5,-diyl), regiorandom poly(3-octylthiophene-2,5,-diyl), poly (3-hexylthiophene)(P3HT), regioregular poly(3-hexylthiophene-2,5-diyl), regiorandom poly(3-hexylthiophene-2,5-diyl), poly(thienylenevinylene) and derivatives thereof, poly(isothianaphthene) and derivatives thereof, tetra-hydrothiophene precursors and derivatives thereof, organometallic polymers, polymers containing perylene units, poly(squaraines) and their derivatives, discotic liquid crystals, polyfluorenes, polyfluorene copolymers, polyfluorene-based copolymers and blends co-polymerized and/or blended with charge transporting and/or light absorbing compounds, tri-phenyl-amines and derivatives, fused thiophene rings and derivatives, and hetero-atom ring compounds with or without substituents, polymer systems with low bandgap, such as poly[2,6-(4,4-bis-(2-ethylhexyl)-4H-cyclopenta[2,1-b; 3,4-b′]-dithiophene)-alt-4,7-(2,1,3-benzothiadiazole)] PCPDTBT, quantum dots, and C60 derivatives, such as 1-(3-methoxycarbonyl) propyl-1-phenyl [6,6] C61) system (PCBM), a pigment or dye chosen from the group of organic pigments or dyes, azo-dyes having azo chromofores (—N═N—) linking aromatic groups, phthalocyanines including metal-free phthalocyanine (HPc), perylenes, naphthalocyanines, squaraines, merocyanines and their respective derivatives, poly (silanes), poly(germinates), 2,9-di(pent-3-yl)-anthra[2,1,9-def: 6,5,10-d′e′f′] diisoquinoline-1,3,8,10-tetrone, and 2,9-Bis-(1-hexyl-hept-1-yl)-anthra[2,1,9-def:6,5,10-d′e′f′] diisoquinoline-1,3,8,10-tetrone, metal oxide gels (e.g., TiO₂ gel), and combinations thereof. In another aspect the nanostructured mold is selected from Si, GaAs, glass, silicon nitride, graphite, SiC, diamond, diamond like carbon, Ni, Cr, Ti, Copper, Pt, SU8, polydimethylsiloxane (PDMS), perfluoropolyether (PFPE), hydrogen silsesquioxane (HSQ), aluminum, titanium, zinc, magnesium, niobium, or alloys thereof. In yet another aspect the one or more nano-structures comprise conical, tubular and other morphologies. In a further aspect the oriented polymer is disposed on an electrode which in turn is disposed on a substrate. The substrate is a part of an optoelectronic device or a solar cell.

The present invention further describes a method of filling a patterned polymer layer disposed on a surface with a material (e.g., polymer, molecules, quantum dots, etc.) comprising the steps of: oxidizing a transfer surface (e.g., rubber); spin-coating the material on the oxidized transfer surface; adjusting a temperature of the polymer coated oxidized transfer surface; wherein the temperature of the coated charge-transfer material is below the glass transition temperature of the patterned polymer layer disposed on the surface; contacting the coated and oxidized transfer surface with the patterned polymer layer disposed on the surface; applying heat and pressure to the patterned polymer layer disposed on the surface and the material-coated oxidized transfer surface stack; followed by temperature adjustment of the stack, wherein the temperature is lower than glass transition temperature of the patterned polymer layer disposed on the surface to avoid structure deformation of the patterned polymer; flowing the material from the coated oxidized transfer surface into the patterned polymer layer disposed on the surface followed by finally releasing the oxidized transfer surface from the stack.

In another aspect the surface comprises a substrate or an electrode selected from silicon, polysilicon, glass, plastic, indium-tin-oxide (ITO) or carbon nanotubes or metal. In yet another aspect the transfer surface is oxidized with an oxygen plasma. In a further aspect the method is used to deposit a charge-transfer material layer on a first interdigitating nano-structured polymer layer; wherein said deposition is used to fabricate an optoelectronic device or a solar cell.

In one aspect the transfer surface comprises polydimethylsiloxane or other silicon based rubber-like organic polymers and the patterned polymer layer and the material is selected from poly(para-phenylenevinylene) derivatives, such as poly[2-methoxy-5-(2′-ethyl-hexyloxy)-1,4-phenylene vinylene] (MEH-PPV) or (poly-[2-(3,7-dimethyl-octyloxy)-5-methyloxy]-PPV (MDMO-PPV), poly(para-phenylenevinylene) (PPV), PPV copolymers, poly(thiophene) and derivatives, regioregular poly(3-octylthiophene-2,5,-diyl), regiorandom poly(3-octylthiophene-2,5,-diyl), poly (3-hexylthiophene)(P3HT), regioregular poly(3-hexylthiophene-2,5-diyl), regiorandom poly(3-hexylthiophene-2,5-diyl), poly(thienylenevinylene) and derivatives thereof, poly(isothianaphthene) and derivatives thereof, tetra-hydrothiophene precursors and derivatives thereof, organometallic polymers, polymers containing perylene units, poly(squaraines) and their derivatives, discotic liquid crystals, polyfluorenes, polyfluorene copolymers, polyfluorene-based copolymers and blends co-polymerized and/or blended with charge transporting and/or light absorbing compounds, tri-phenyl-amines and derivatives, fused thiophene rings and derivatives, and hetero-atom ring compounds with or without substituents, polymer systems with low bandgap, such as poly[2,6-(4,4-bis-(2-ethylhexyl)-4H-cyclopenta[2,1-b; 3,4-b′]-dithiophene)-alt-4,7-(2,1,3-benzothiadiazole)] PCPDTBT, quantum dots, such as CdSe, and C60 derivatives, such as 1-(3-methoxycarbonyl) propyl-1-phenyl [6,6] C61) system (PCBM), a pigment or dye chosen from the group of organic pigments or dyes, azo-dyes having azo chromofores (—N═N—) linking aromatic groups, phthalocyanines including metal-free phthalocyanine (HPc), perylenes, naphthalocyanines, squaraines, merocyanines and their respective derivatives, poly (silanes), poly(germinates), 2,9-di(pent-3-yl)-anthra[2,1,9-def: 6,5,10-d′e′f′] diisoquinoline-1,3,8,10-tetrone, and 2,9-Bis-(1-hexyl-hept-1-yl)-anthra[2,1,9-def:6,5,10-d′e′f′] diisoquinoline-1,3,8,10-tetrone and combinations thereof.

### BRIEF DESCRIPTION OF THE DRAWINGS

For a more complete understanding of the features and advantages of the present invention, reference is now made to the detailed description of the invention along with the accompanying figures and in which:

FIGS. 1A to 1E show the structure of a photovoltaic device or solar cell using molded polymer nanostructures with charge-transfer functionality: (1A) cross-section of device architecture; (1B) Top view of the functional material morphology; (1C) an example of orthogonal arrangement of posts with circular or square shapes; (1D) an example of checker boarder morphology; and (1E) grating morphology;

FIGS. 2A to 2G summarize the fabrication process of porous membrane: (2A) two-step anodization process to form porous alumina membranes on A1 plates; (2B) schematic of anodic alumina template; (2C) Electron micrograph of successfully formed anodic alumina templates; (2D) Electron micrograph of freestanding anodic alumina membrane; (2E) transfer the anodic metal films to other materials such as Si wafer; (2F) cross-sectional SEM of anodic alumina membrane on Si after etching away the rough barrier layer; and (2G) shows electron micrograph of Si templates successfully transferred from anodic alumina membrane as shown in 2D;

FIGS. 3A to 3C, show examples of molds used to make similar interdigitized morphologies: (3A) pillar molds to be used to mold nanopores in polymer; and (3B) and (3C) show cross-sectional electron micrographs of grating molds of 200 nm pitch and 80 nm and 30 nm trench width, respectively;

FIGS. 4A to 4I show the steps in the fabrication process to make photovoltaic devices based on nanostructured charge-transfer polymer films using polymer molding with porous templates;

FIGS. 5A and 5B are two magnifications of SEMs of molded polymer structures using process of the present invention;

FIGS. 6A to 6D show 45 degree cross-sectional views (electron micrographs) of polymer nanostructures with different aspect ratio and morphology: (6A) 150 nm tall, 50 nm diameter polymer nanoposts; (6B) 300 nm tall nanoposts; (6C) 900 nm tall nanoposts; and (6D) nanopores or nano-mesh network in polymer is formed using replicated nanopost templates, forming a negative image of the previous 6A-6C morphology;

FIGS. 7A to 7D show SEM images of imprinted nanostructures in P3HT: (7A) pillar array of 80 nm diameter and 250 nm tall; (7B) 700 nm in height; (7C) P3HT pores with well defined <20 nm walls; and (7D) 20 nm wide, 100 nm tall gratings;

FIG. 8 is the SEM image of PCBM deposition on 40 nm tall and 80 nm wide P3HT pillars;

FIG. 9 shows structures of modified PCBM containing various terminal groups;

FIG. 10 is a schematic of a reversal imprinting or transfer printing method to deposit the PCBM;

FIG. 11 is a plot of the current v/s voltage of a fabricated solar cell device with 40 nm tall and 80 nm wide pillars. Nanostructured polymer morphology results in improved fill factor (FF) or the efficiency of the device;

FIG. 12 is a plot of the effective interface area as a function of pitch and height of the nanostructures. Dotted lines are for pillar/pore nanostructures while the solid lines are for gratings. The study was done with a 1:1 spacing ratio;

FIG. 13 shows the results of the X-ray diffraction (XRD) studies on imprinted and non-imprinted polymer films: (13A) out of plane XRD shows that the molded P3HT nanostructures (gratings, pillars, and pores) has higher crystallinity for higher charge mobility than original unmolded P3HT; and (13B) in plane XRD (also known as Grazing Incidence In-Plane X-Ray Diffraction or GIXRD) shows that the molded P3HT gratings have a vertical chain alignment or vertical π stacking, which are favorable polymer chain configuration for high charge mobility and high current leading to better device efficiency; and

FIG. 14 shows typical configurations of P3HT crystalline orientation: (14A) vertical stacking of P3HT side-chains resulting in poor charge mobility; (14B) π stacking orientation for good current conductivity; and (14C) vertical chain alignment in P3HT nanopillars, as observed using atomic force microscopy (AFM) and XRD in FIG. 13. The nanoimprint process results in chain orientation of 14B or 14C.

### DETAILED DESCRIPTION OF THE INVENTION

While the making and using of various embodiments of the present invention are discussed in detail below, it should be appreciated that the present invention provides many applicable inventive concepts that can be embodied in a wide variety of specific contexts. The specific embodiments discussed herein are merely illustrative of specific ways to make and use the invention and do not delimit the scope of the invention.

To facilitate the understanding of this invention, a number of terms are defined below. Terms defined herein have meanings as commonly understood by a person of ordinary skill in the areas relevant to the present invention. Terms such as “a”, “an” and “the” are not intended to refer to only a singular entity, but include the general class of which a specific example may be used for illustration. The terminology herein is used to describe specific embodiments of the invention, but their usage does not delimit the invention, except as outlined in the claims.

Large-area, inexpensive organic solar cells on plastic substrates find widespread applications, from consumer electronics to commercial power production. However, even the best demonstrated organic solar cells had lower power conversion efficiency or PCE (˜6%) [2-7] in comparison to their inorganic counterparts (>10%). This low energy conversion efficiency becomes a bottleneck for organic solar cell technology towards commercialization. Such low efficiency stems from the tradeoff between optical absorption and internal quantum efficiency. Internal quantum efficiency is comparatively low primarily due to the short diffusion length of photo-generated electron-hole pairs or excitons in polymer (10-20 nm range). [8-9]

Charge dissociation and transport are the key processes that affect the power conversion efficiency. Recently, many techniques have been developed to enhance these processes, including using e- or hole injection layers, dyes, quantum dots, C60 derivatives, such as the 1-(3-methoxycarbonyl) propyl-1-phenyl [6,6]C61 system (PCBM) mixed with donor polymers like poly(3-hexylthiophene) or P3HT, in a form of bulk heterojunction (BHJ. [2,10-17]. The BHJ technology has improved the PCE of organic solar cells (to about 5%) due to the formation of interpenetrating nanoscale phases and large interface to volume ratio, allowing more efficient exciton dissociation. In BHJ, heterojunction, morphology is the most critical factor affecting device performance since it directly determines the exciton dissociation efficiency and charge transport. Most BHJs are formed, using solvent processing, in a thin film of composite mixture or blend of polymer and fullerene. [2, 7, 8, 15, 20, 21] Despite the great progress made in blend BHJ in the last decade, such chemically defined morphology has fundamental limitations in achieving PCE>5%. For example, the overlapping of discrete and randomly distributed phases causes significant charge pair recombination, as well as a significant amount of disorder in the polymer chains resulting in low carrier mobility. In addition, light absorption is inefficient due to the thin active layer (˜100 nm) that results from such processing.

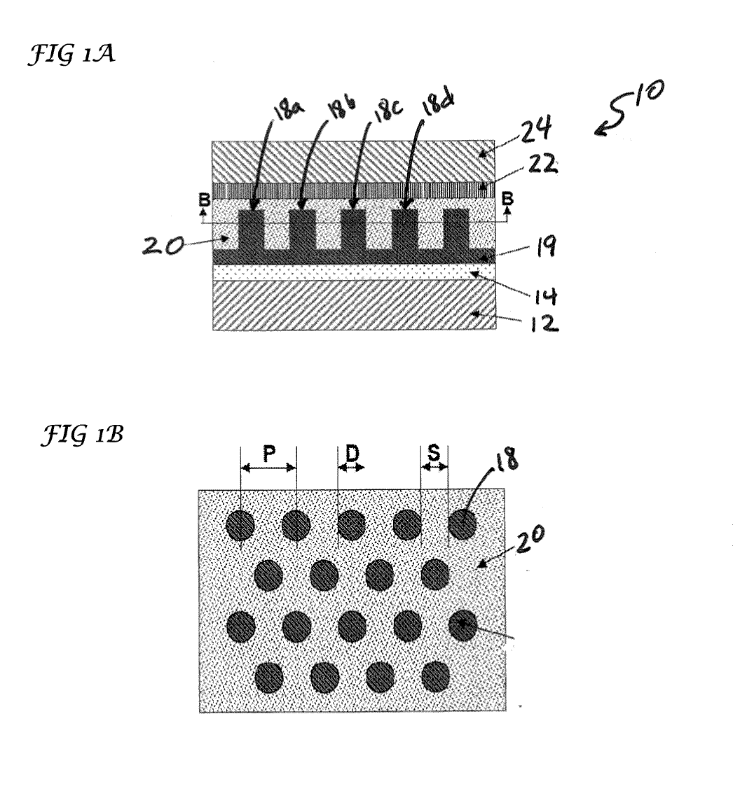

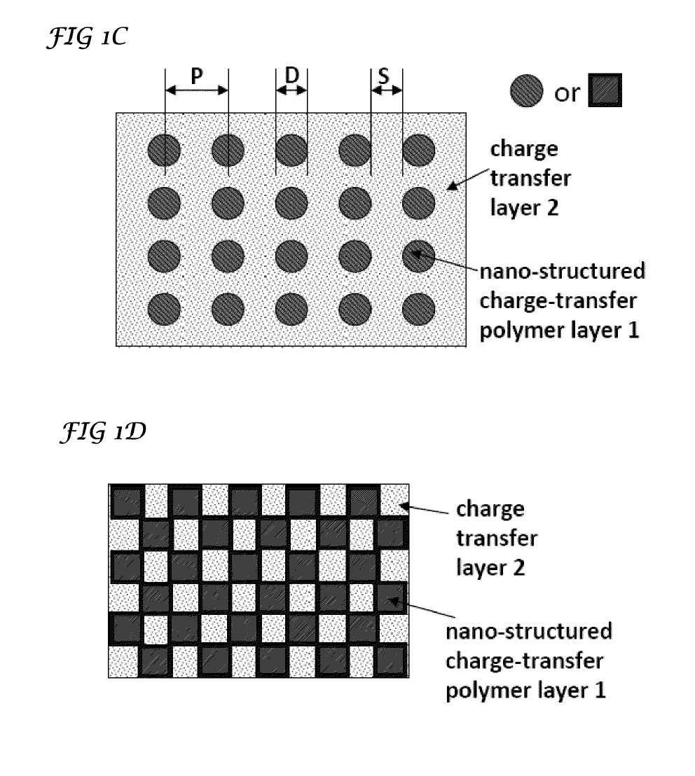

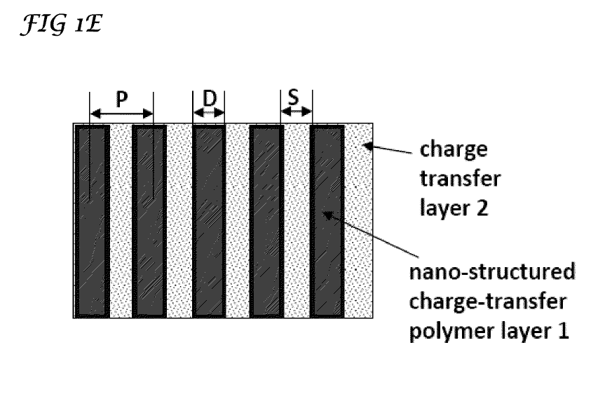

Many of the above-mentioned problems can be considerably alleviated if a vertically bicontinuous or interdigitized heterojunction nano-morphology similar to FIG. 1 can be achieved. Recent simulations suggest similar morphology enables as much as 80% internal quantum efficiency, in comparison to 15% for most BHJ blends [4], signifying a 5× improvement in PCE. The nanoscale interdigitized morphology decouples absorption depth and charge transport channel from the diffusion length, allowing highly efficient lateral exciton diffusion and vertical charge transport with reduced recombination.

Very recently, there has been emerging interest in using lithography to define such morphology due to its high patterning resolution, precision and reproducibility. For example, Kim and Guo et al. have reported the use of nanoimprint lithography to define 500 nm wide gratings in deprotectable polythiophene derivative materials [3]. However, the advantage of NIL is not fully realized due to their large dimensions (0.5 μm in width) used and choice of materials resulting in a low PCE (˜0.8%). The present invention describes a nanoimprint lithography method, wherein an unique high-density nanopore/pillar nanoimprint mold transferred from anodic alumina to make P3HT or PCBM nanostructured solar cells with PCE already at ˜3%[22, 23].

The present invention permits, for the first time, the formation of highly-ordered, nanoscale, porous templates of low roughness over large areas. The high quality template paves a way for uniform polymer molding towards device manufacturing. Using the methods of the present invention it is possible to make periodic nanostructures in charge-transfer materials enables high efficiency of power conversion for solar cells. It is also possible to form high-aspect ratio nanostructures in functional polymers. The method of the present invention also allows for advanced photovoltaic devices with lower cost compared to lithographic approaches.

The present invention describes a nanoimprint lithography method with an unique mold technology to define nano-morphology in polymer-fullerene solar cells with ultrahigh precision. The nanoimprint lithography process improves polymer crystallinity and vertical chain alignment, carrier mobility, and light absorption. Combining these improvements may result in PCE of 7-12% for the P3HT-fullerene system.

From the manufacturing perspective, NIL is the only technology offering low cost, high throughput, and sub-20 nm patterning resolution [18]. For solar cell applications, the Department of Energy (DOE) requires a manufacturing process capable of producing coupon sized devices, at the minimum. Cost-effectively patterning high-density nanostructures over this size is a challenge. NIL meets this requirement, by the fabrication of large area nanostructured nanoimprint molds. The present invention describes an inexpensive large area mold fabrication technique by transferring anodic alumina patterns to crystalline Si that allows for patterning high-density polymer nanostructures over coupon size substrates in minutes. These nanoimprint mold fabrication and NIL processes can be extended to roll-to-roll printing or the step and imprint process that has been demonstrated for high-density storage applications [3, 19, 20] for low cost mass-production of nanostructured organic solar cells.

As used herein, “electron affinity” refers to the energy needed to detach an electron from a singly charged negative ion, thus restoring the neutrality of an atom or molecule. Electron affinity is often denoted as Eₑₐ. The electron affinity of a dielectric is close to the work function of an electrode, that is, it is easy for electrons to move from the metal into the non-metal. Electrode materials must be chosen so that the electrode work function is greater than the electron affinity of the dielectric, otherwise, electrons migrate to the conduction band producing a net transport of charge, meaning current will bleed from the capacitor, commonly referred to as the “leakage current”.

This invention solved the fabrication limitation of using traditional imprinting or molding to produce large area polymeric solar cells. The present invention also solves the problems associated with self-assembled polymer and the current leakage that results thereby. The availability of the compositions and methods of the present invention allows the manufacture of highly ordered and high aspect ratio nanostructures in charge-transfer materials that greatly improve the power generation efficiency of solar cells.

The present invention describes nanoimprint lithography (NIL) [18] to define an optimal nano-morphology for polymer-fullerene solar cells (SCs) that is cost-effective, and has improved crystallinity and polymer chain orientation to achieve 7-12% power conversion efficiency (PCE). This expected high power-conversion efficiency stems from periodic arrays of interdigitized heterojunction morphology, which is an optimal morphology to achieve high PCE [2-4]. The high-density vertically aligned bicontinuous hole and electron transport materials allow for efficient charge pair dissociation at the interface, vertical carrier transport to electrodes with little recombination, and a thicker active layer (200-400 nm compared to 100 nm of current bulk-heterojunction or BHJ) for better optical absorption. In addition to defining the nano-morphology, the nanoimprint lithography process would dramatically improve the structural and optical properties of the functional polymer material (P3HT), giving higher crystallinity and more favorable chain orientation, leading to high charge mobility. The combination of above-mentioned effects will overcome the key limitations of the current blend BHJ approach yielding much higher PCE.

FIG. 1A shows a cross-sectional, side view of a photovoltaic device or solar cell (SC) 10 based on nanostructured polymer charge-transfer materials that increase the efficiency of energy conversion. The photovoltaic device 10 includes a first substrate 12 onto which an electrode 14 has been formed, grown, sputtered, or deposited. A first layer of nanostructured periodic array of an active polymer 16 is shown with several interdigitating nanostructure units, (e.g. cylindrical posts 18a-18e on a polymer base 19, wherein the posts 18a-18e will interdigitate with a second layer of second nanostructured active polymer 20. A second electrode 22 is shown contacting the second nanostructured active polymer 20 onto which a second substrate 24 is contacted. The electrodes (14 or 22) can be either an anode or a cathode. The first and second layers of nanostructured periodic arrays of active polymers (16, 20) form an electron-acceptor:hole-acceptor pair. Typically, the anode will interface with the hole-transfer layer and the cathode will interface with the electron-transfer layer. The repeating nanostructure units in the polymer 18 can also be pores, square shaped posts, hollow tubes, honeycombs, irregular pores, etc.

FIG. 1B is a top view of the example photovoltaic device or solar cell (SC) 10 shown in FIG. 1A. The high efficiency of the photovoltaic device 10 stems from the nanostructured periodic arrays of active polymer layers made by polymer molding or nanoimprint lithography. The highly-ordered polymer nanostructures as active SC region have 10-100 nm pore diameter (D) for the interdigitating cylindrical posts 18a-18e. Between the interdigitating cylindrical posts 18a-18e there can be a 10-100 nm spacing with (S), and >2 aspect ratio (height to diameter as see in FIG. 1A). The distance between post centers is shown as P. Monte Carlo simulations provide that these ordered polymer nanostructures can achieve an internal quantum efficiency of ˜80% compared to conventional polymer blending (<15%)[4]. Excitons generated from light absorbance in nanostructured charge-transfer polymer array will be able to diffuse to the interfaces of heterojunction since the diameter of polymer arrays is close to its diffusion length. Dissociated hole and electrons then propagate to cathode and anode respectively without hindrance in their pass ways. Surprisingly, the polymer layer undergoes an imprint-induced nano-crystallization process that aligns polymer chains vertically, e.g., forming π stacking that increase the charge mobility of the polymer.

FIGS. 1C-1E shows similar interdigitalized morphology design using different repeating units and geometry, e.g. orthogonal arrangements of nanoposts, checker-board arrangement of square posts, and nanogratings, respectively. The design of the morphology or geometry can be modified to obtain one or more design shapes and/or structures that maximize, e.g., one or more of the following: charge flow, strength, resilience, the ability to bend or twist to obtain similar cross-sectional view of FIG. 1A. The size of the repeating unit 18 can be varied, that is, it is not necessarily the same size, height or shape throughout the mold and hence the imprint.

The material selection for the semiconductor (SC) device in FIG. 1 can be very broad. For example, the substrates may be, e.g., silicon, polysilicon, glass, plastic or metal, and can be used as substrate 1 and 2. One of the substrates should have good transparency for visible lights. ITO or carbon nanotubes sheets [21] can be used as anode material to interface the hole-transfer layer. Aluminum and other metal materials can be used as cathode to interface electron-transfer layer of the SC.

The charge transfer materials may be one or mixed material of the following: poly ara-phenylenevinylene) derivatives, such as poly[2-methoxy-5-(2′-ethyl-hexyloxy)-1,4-phenylene vinylene] (MEH-PPV) or (poly-[2-(3,7-dimethyl-octyloxy)-5-methyloxy]-PPV (MDMO-PPV), poly(para-phenylenevinylene) (PPV), PPV copolymers, poly(thiophene) and derivatives, regioregular poly(3-octylthiophene-2,5,-diyl), regiorandom poly(3-octylthiophene-2,5,-diyl), poly (3-hexylthiophene) (P3HT), regioregular poly(3-hexylthiophene-2,5-diyl), regiorandom poly(3-hexylthiophene-2,5-diyl), poly(thienylenevinylene) and derivatives thereof, poly(isothianaphthene) and derivatives thereof, tetra-hydrothiophene precursors and derivatives thereof, organometallic polymers, polymers containing perylene units, poly(squaraines) and their derivatives, discotic liquid crystals, polyfluorenes, polyfluorene copolymers, polyfluorene-based copolymers and blends co-polymerized and/or blended with charge transporting and/or light absorbing compounds, tri-phenyl-amines and derivatives, fused thiophene rings and derivatives, and hetero-atom ring compounds with or without substituents, such as poly[2,6-(4,4-bis-(2-ethylhexyl)-4H-cyclopenta[2,1-b; 3,4-b′]-dithiophene)-alt-4,7-(2,1,3-benzothiadiazole)] or PCPDTBT, quantum dots, C60 derivatives, such as 1-(3-methoxycarbonyl) propyl-1-phenyl [6,6]C61) system (PCBM). Another charge material can also include a pigment or dye chosen from the group of organic pigments or dyes, azo-dyes having azo chromofores (—N═N—) linking aromatic groups, phthalocyanines including metal-free phthalocyanine (HPc), perylenes, naphthalocyanines, squaraines, merocyanines and their respective derivatives, poly (silanes), poly(germinates), 2,9-Di(pent-3-yl)-anthra[2,1,9-def: 6,5,10-d′e′f′] diisoquinoline-1,3,8,10-tetrone, and 2,9-Bis-(1-hexyl-hept-1-yl)-anthra[2,1,9-def:6,5,10-d′e′f′]diisoquinoline-1,3,8,10-tetrone [22], and also metal oxide gel such as TiO₂ gel.

Fabrication of porous template based on anodic metal template. There are several important advantages of using anodic metal templates for the polymer molding process to make SCs. First, the templates offer much lower cost compared to lithographic manufactured templates. Second, the nanostructures can cover a much larger area on the template using anodization process compared to lithography methods. Third, the anodization process can produce high aspect ratio pores from tens of nanometer to a few microns deep, which is difficult for lithography methods and even in those cases includes very large variability between the various features. The high aspect ratio of the pores are important for high energy conversion efficiency since thick charge transfer films can be used and light absorbance may be higher. Besides, the manufacturing cost will be much cheaper compared to using lithographic methods.

The anodic alumina template (AAT) can be made by two-step anodization of aluminum films, which are well research in the last decade [23]. Any anodizable material may be used to make an AAT, e.g., titanium, zinc, magnesium, niobium and alloys thereof. The pore diameter, pore-to-pore spacing, and length of the pores or tubes can be defined by controlling the voltage, current, and acids used in the electrochemical processes. These films have been used as a mask for nanowires growth [24], nanoparticles deposition, [25] and also for electrical devices [22]. Porous membranes of materials other than alumina can be made by replicating AAT using masked evaporation and/or etching of materials underneath the membrane [26].

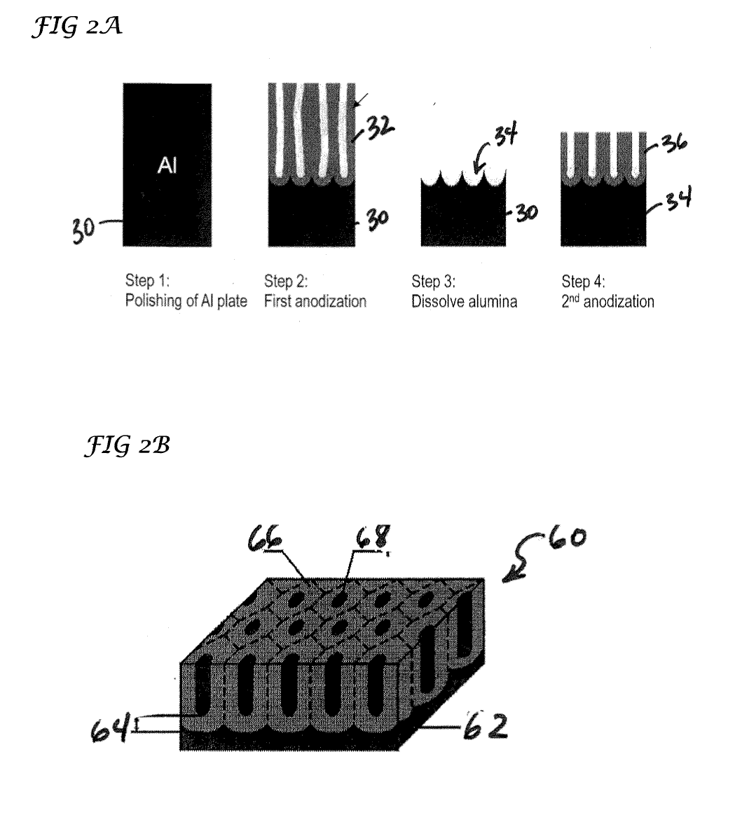

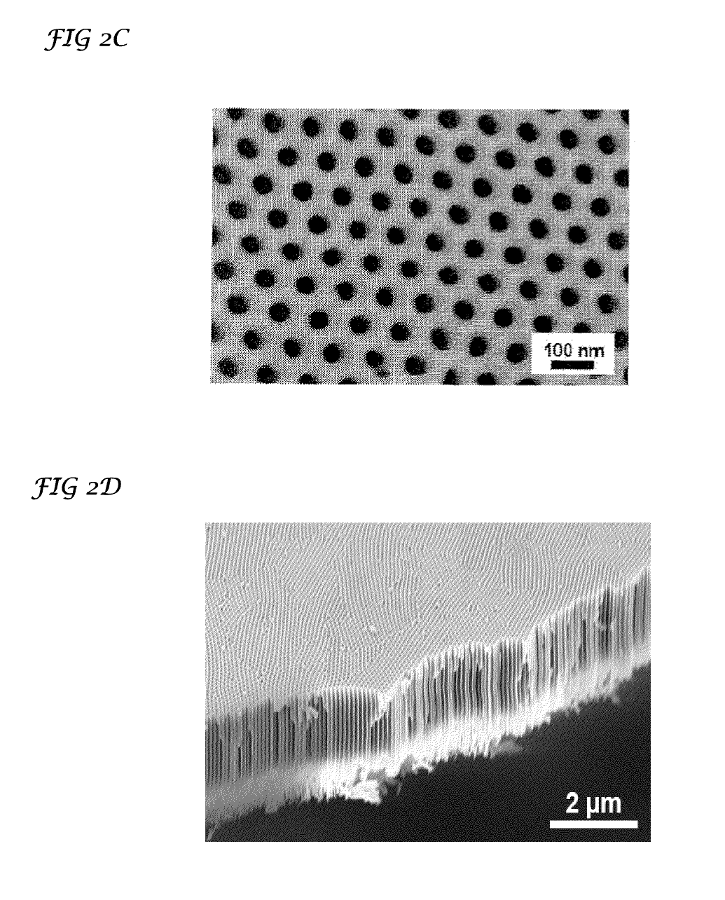

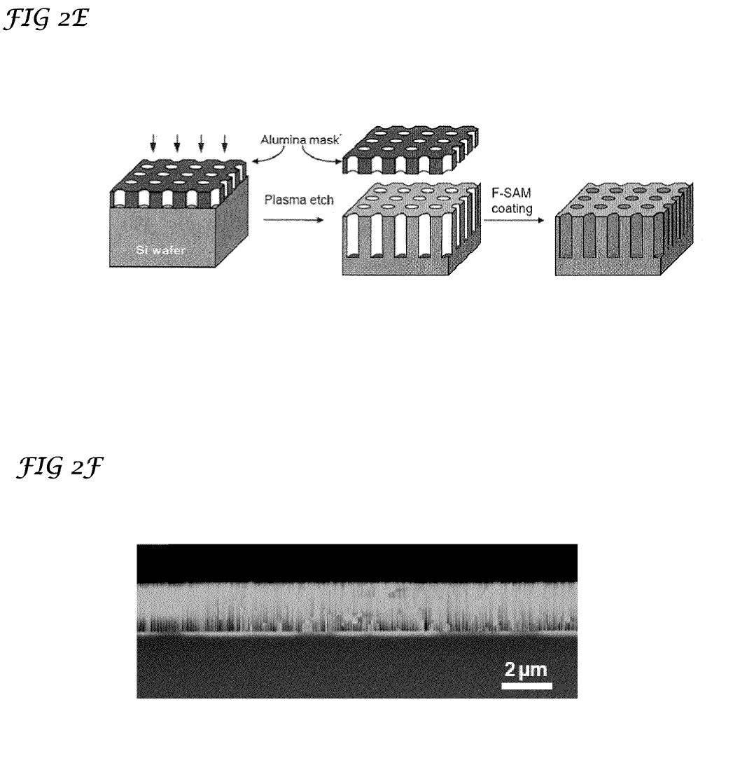

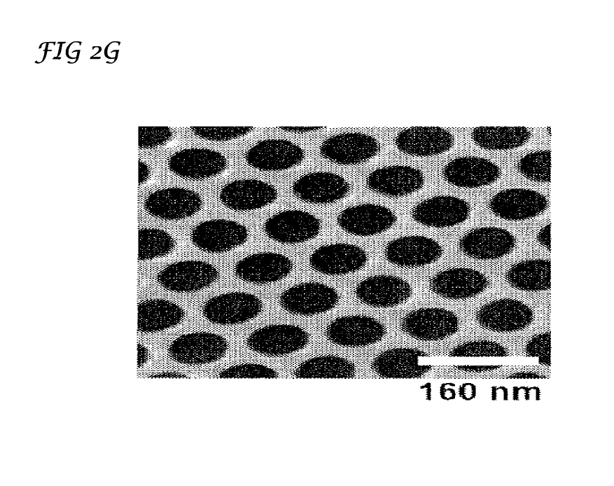

FIG. 2A illustrates the first step in a typical two-step anodization process to make an AAT. The key requirement of using the anodic metal templates to mold polymer nanostructures over large area is a reduced or low surface roughness. In the first step, mechanic polishing of a plate 30 (e.g., an aluminum template) may be conducted using a set of diamond lapping films and alumina lapping films, followed with electrochemical polishing. A first anodization is conducted for form anodized aluminum layer 32. The anodized aluminum layer 32 is then dissolved to form anodization pores 34. A second anodization step is then conducted that form a second layer of anodized aluminum 36 with thicker side walls. FIG. 2B shows the schematic of a formed AAT 60, which includes a substrate 62, which has an anodized barrier layer 64 and includes multiple cells 66, each of which includes a pore 68.

The AAT can be released from the Aluminum substrate to form porous membrane, which can be used to make porous molds in other materials. To make anodic alumina membrane or AAM, after the second anodization step as described in the previous paragraph, the anodization voltage is gradually decreased. During such a voltage reduction process, the nanopores get smaller, branch out, and form a thin barrier layer. After the voltage reduction, the thin Al₂O₃ barrier layer at the interface of AAM and the remaining A1 plate was partially dissolved in 10 wt % H₃PO₄ solution. AAM of 1-2 in² areas was detached from the A1 plate. FIG. 2C shows an SEM image of a freestanding AAM. The AAM contains uniform pores of 50-60 nm in diameter and 2-3 μm in length. Top surface of the AAM is very smooth, while the backside of the AAM is the rough barrier layer. The A1 foil was carefully washed with purified water several times and AAM film was collected with a thin parafilm backing paper.

FIG. 2E shows an isometric view of the steps in which an alumina mask is used to make nanoporous molds in other materials such as Si. The direct use of freestanding AAM as an etch mask has two problems. First, it is hard to transfer large pieces of the thin and brittle AAMs onto Si with conformal contact. Second, the barrier layer of AAM resulted from the voltage reduction process is very rough and blocks the nanopores and Si from plasma etching. For good AAM attachment on the Si substrates, a solvent-assisted AAM attachment process was invented. A few drops of solvent, e.g. isopropyl alcohol, were cast over the AAM immediately after the membrane is placed on the Si surface. The solvent spreads quickly over the entire contact area between the membrane and Si, removing the air at the interface. The surface tension of the solvent during the spreading generates capillary forces to pull the membrane towards Si, thus results in uniform contact between the two surfaces. After the solvent dried, the AAM remains attached to the Si substrate due to Van der Waals and Coulomb forces. The conformal contact of AAM with Si substrate can be further improved during plasma etching, where electrostatic forces between the Si and AAM (due to substrate bias and ion bombardment) generate conformal attachment and eliminate the micro scale voids.

As shown in FIG. 2E, the AAM is placed on Si with the rough barrier side facing up. For good pattern transfer from the AAM to Si, an Ar plasma etching process is used to remove the rough barrier layer, yielding uniform AAM pores and reducing the thickness of the AAM, as shown in FIG. 2F. It is observed that conformal contact between the AAM and Si was achieved after the first etching step. The attachment of freestanding AAM on Si was found to be similar to the direct-grown AAM from thin A1 film deposited on Si [18]. However, the pore ordering and uniformity is better since a two-step anodization was used to prepare the AAM. Another benefit of the etching process is that it allows us to use thicker AAM (>3 μm) so that we can handle bigger AAM sample easily. The second etch step was used to transfer AAM structures into underneath Si using Ar:Cl₂ (1:1) plasma at the ICP power of 300 W, RF bias power of 200 W, and a consecutive pressure of 5, 10, 15 mTorr for 3 mins for each step to achieve uniform pore profile and high aspect ratio. Increasing plasma pressure gradually when the pores get deeper is necessary to maintain uniform lateral Si etching rate along the pore depth. SEM images in FIG. 2G show the top view of the etched Si nanopores. Pores of uniform diameter (80 nm), spacing (20 nm), controllable depth (200-900 nm), and cylindrical profiles were obtained. These dimensions can be controlled by adjusting the plasma pressure, ICP and bias power, and Cl₂ and Ar ratio. After the etching, the AAM was removed using a tape and the porous Si mold was cleaned in piranha solution for 30 minutes. The Si mold was then soaked in 1-2% perfluorodecyltrichlorosilane or CF₃—(CF₂)₇—(CH₂)₇-SiCl₃ in n-heptane for 5 minutes, dried in N₂, and baked at 100° C. for 10 minutes. Such treatment resulted in a super hydrophobic mold with surface energy of 17 mJ/m² for successful demolding.

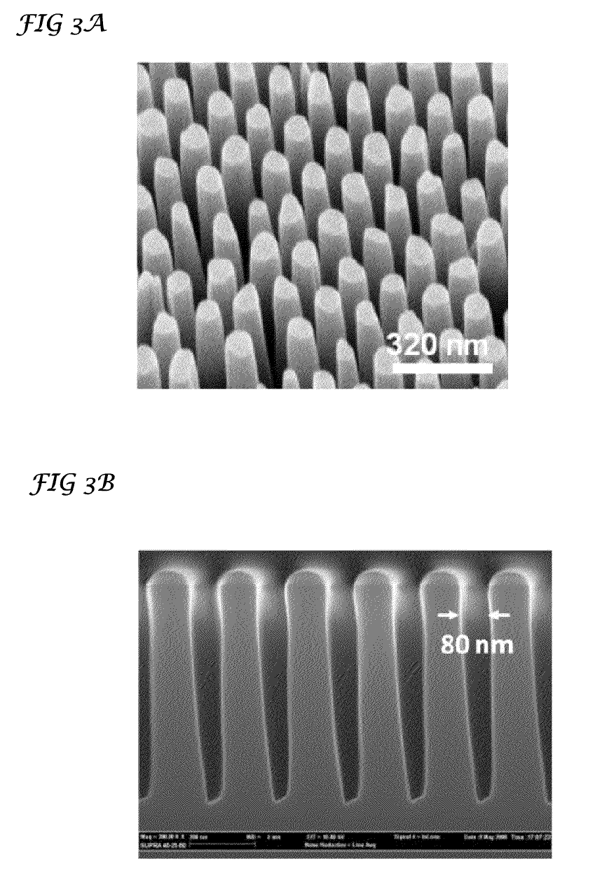

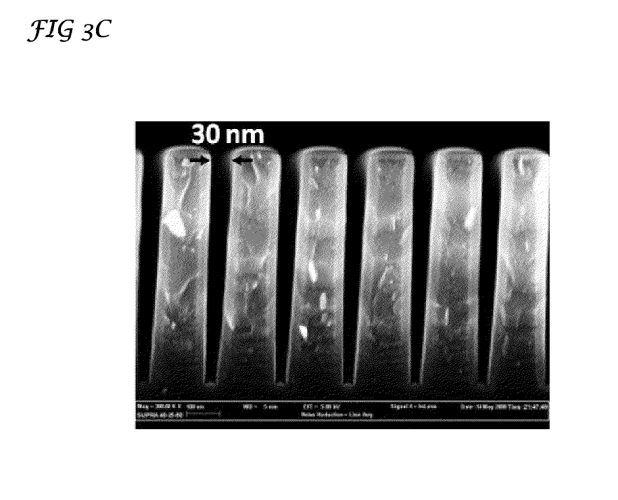

It was found that the resulting Si mold offers sub-nm surface smoothness, high hardness (much better than AAO), and independent control of feature diameter, pitch, and depth/height. As discussed previously, the availability of this large-area nanoimprint mold is crucial in making coupon-size nanostructured solar cells, which is not possible with conventional lithography. This mold fabrication process can be applied to other solid materials such as glass, diamond like carbon, SiC, etc. Both positive and negative tones of the mold can be made in similar ways. FIG. 3A shows an SEM image of nanopillar molds made in Si by replicating the nanoporous mold through nanoimprint in resist, which is then used as a mask to etch Si substrate. The present invention also includes templates and use of these templates to make the SCs shown in FIG. 1.

Derivative templates can also be made in soft materials for roll to roll replication process. Soft molds made of poly-dimethylsiloxane (PDMS) and perfluoro-polyethers (PFPE) can be obtained by casting PDMS or PFPE precursors over the AATs and then cure them thermally or using UV exposure.

To prepare nanowires/grating Si nanograting molds of 100 nm line/space, 100 nm in depth, and as large as 4 inches, were purchased from Nanonex, which are made by interference lithography. The trench dimension is adjusted by oblique metal evaporation onto nanoimprinted patterns, etching, and controlled Si oxidation process. Using this process, trench width can be well controlled from 20 to 100 nm and depth can be increased up to 1 μm. The pitch of the pattern can also be reduced by using a “frequency-doubling” process established [27-29]. The oxidation process can also be applied to nanopillar/pore molds to fine tune the dimensions.

FIGS. 3A, 3B, 3C, show example molds to make similar interdigitized morphology. (3A) pillar molds to be used to mold nanopores in polymer; (3B) and (3C) show cross-sectional electron micrographs of grating molds of 200 nm pitch and 80 nm and 30 nm trench width, respectively.

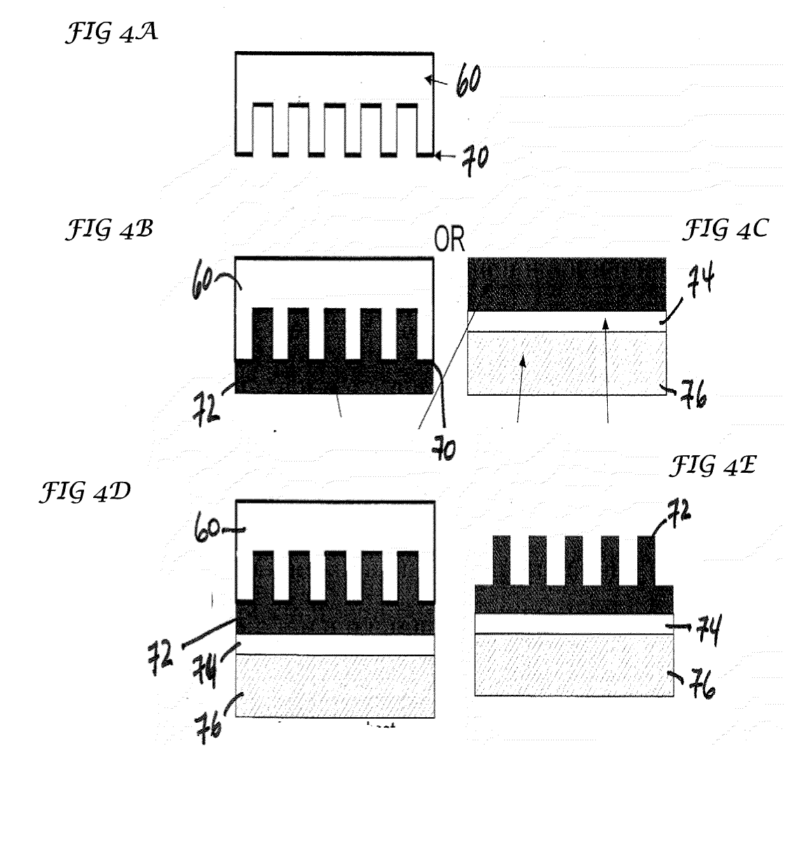

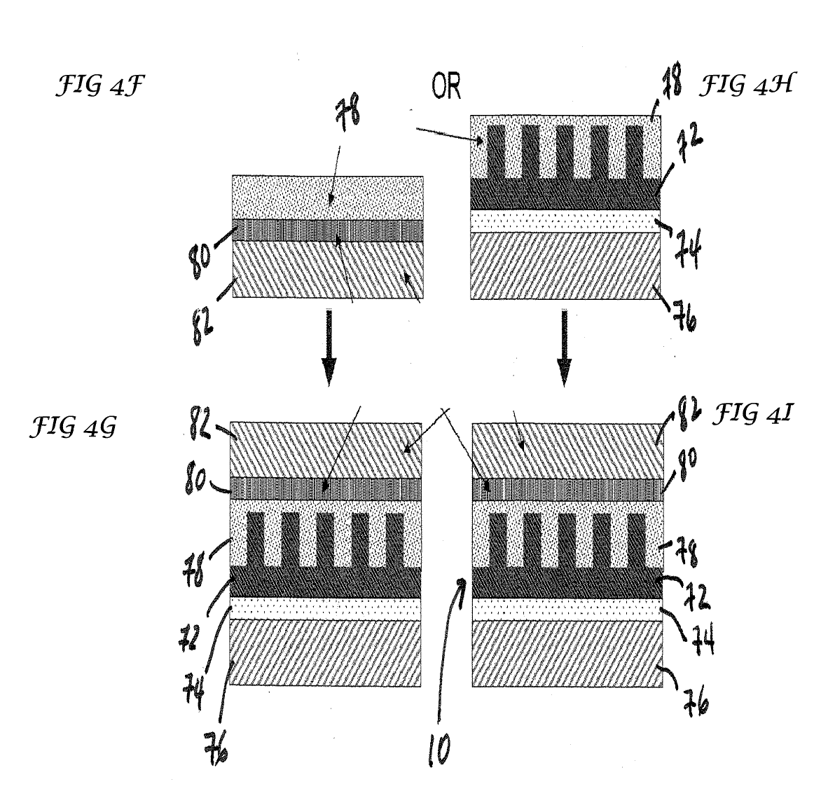

FIGS. 4A to 4I shows several optional fabrication processes for making photovoltaic device or solar cell (SC) 10. After the porous templates 60 are formed, their surfaces will be modified to have a surface energy of 6-50 mJ/cm² to prevent polymer adhesion to the template after molding or imprinting. For example, the surface of the template 60 may be treated with a layer 70, which may be a silane surface treatment, for example, perfluoro-decyl-trichloro-silane (FDTS), methacryl-oxypropyl-trichloro-silane (MOPTS), phenethyl-trichloro-silane (PETS), and their combinations. A first charge-transfer material 72 can be deposited onto the template (FIG. 4B), or alternatively, deposited onto the electrode 74 on a substrate 76 (FIG. 4C) by spincoating, casting, or evaporation. As shown in FIG. 4D, the template 60 and polymer 70 can be applied to an electrode 74 on a substrate 76, e.g., they may be brought into contact in a molding process under a pressure of 0.1-15 MPa, a temperature of 20-300° C. (above the glass transition temperature of the material), and optional UV exposure for curing. The exact imprint conditions depend on what kind of material is used as charge transfer materials. For example, this process can be performed on a commercial nanoimprint system or any other customized systems. After the polymer 73 fills the pores of the template 60, the system was cooled down to below the glass transition temperature of the material and the template is detached from the electrode 74 and substrate 76 (FIG. 4E).

A layer of a second charge-transfer material 78 can be deposited on the second electrode 80 coated second substrate 82 (FIG. 4F), or alternatively, a layer is deposited onto a patterned first charge-transfer material 72 directly (FIG. 4H). For the option shown in FIG. 4F, another imprinting or molding process can be used to bond the first and second charge-transfer material layers (72, 78) and two substrates (76, 82) together to from the SCs (FIG. 4G). For the process of FIG. 4H, second electrode 80 and second substrate 82 can be deposited on the second charge transfer layer 78 to form the SCs. The invention covers both manufacturing processes.

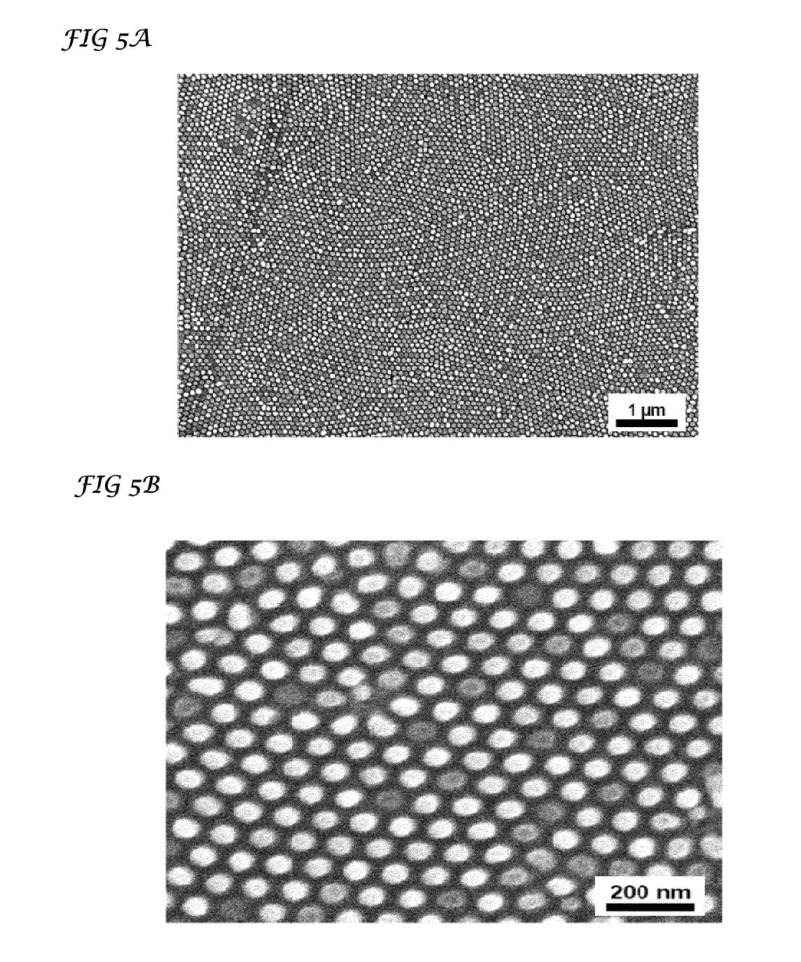

FIGS. 5A and 5B show two magnifications of electron micrographs of imprinted polymer pillars using porous template prepared by anodization. The molding process is smooth and uniform over large areas. Nanostructures with diameter 40-80 nm and spacing of 20-40 nm were successfully formed.

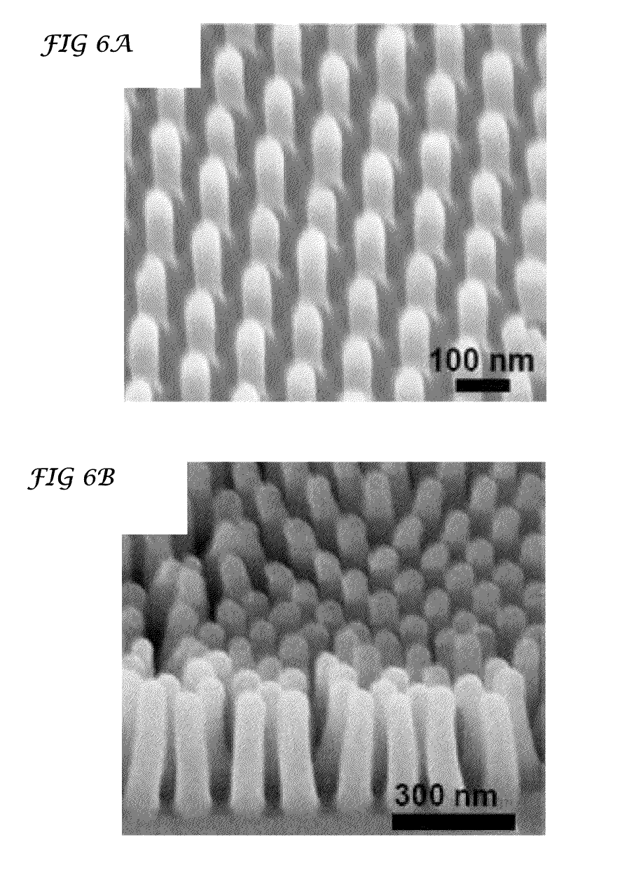

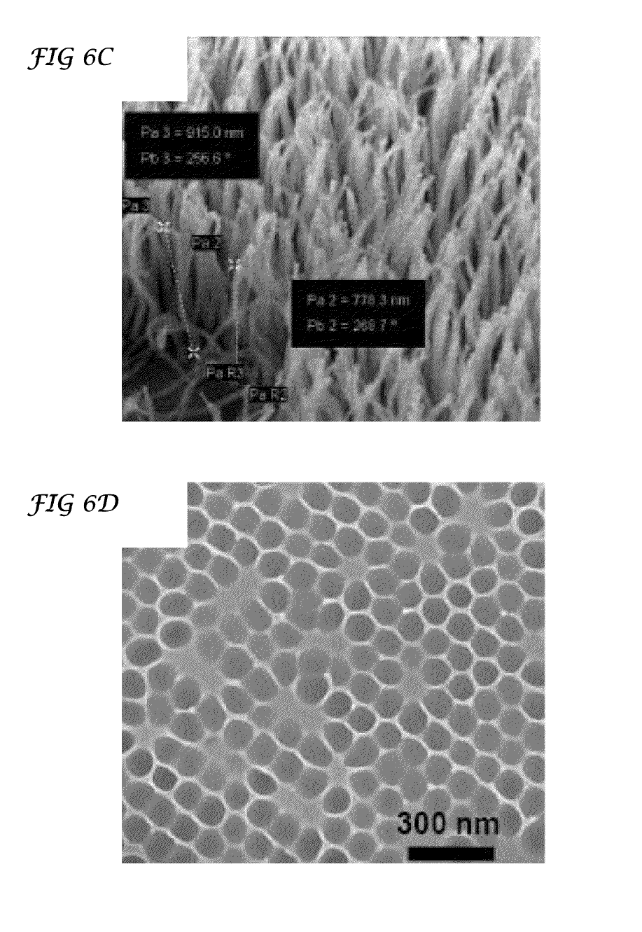

FIGS. 6A to 6C shows polymer nanoposts with height of 150 nm, 300 nm, 600-900 nm, respectively, demonstrating the capability of the process to make high aspect ratio nanostructures in functional polymers. FIG. 6D also demonstrates the formation of nanopores or nano-mesh network morphology which is negative copy of nanopost templates.

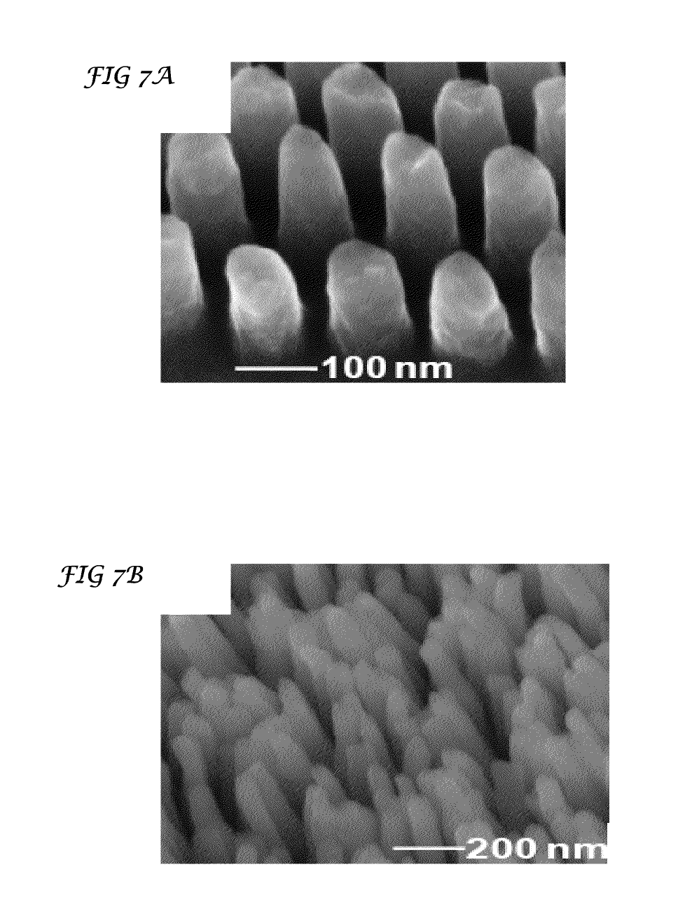

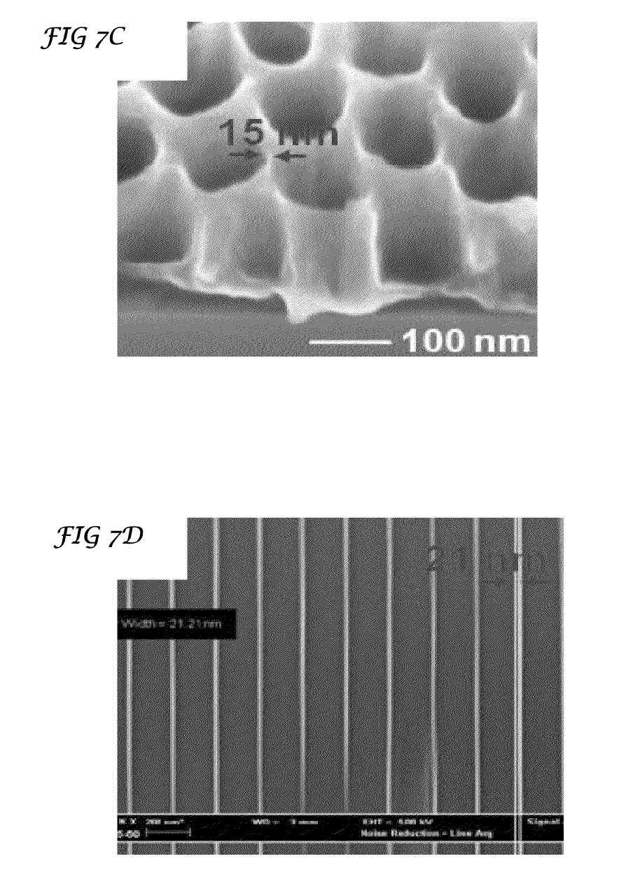

FIGS. 7A to 7D show SEM images of imprinted nanostructures in P3HT. (7A) Pillar array of 80 nm diameter and 250 nm tall; (7B) 700 nm in height; (7C) P3HT pores with well defined <20 nm walls; and (7D) 20 nm wide 100 nm tall gratings. Thermal nanoimprinting was used to produce large areas of P3HT nanopillars, pores, and gratings or nanowires of varying lateral dimensions (20-100 nm) and height (100-500 nm). The studies have been successful imprinting in P3HT (FIGS. 7A-7D), 20 nm wide 100 nm tall (FIG. 7C) and 80 nm wide and 700 nm tall P3HT nanostructures (FIG. 7B) have been demonstrated.

Selection of the imprint conditions is strongly related to physical properties of the polymer. Typically 20-50° C. above the glass transition temperature (T_{g}) of polymer was chosen in the study for reasonably lowering the viscosity to fill the nanoimprint mold. However, P3HT undergoes a twist-glass transition, which is a quasi-ordered phase transition of liquid crystals (LCs) and plastic crystals (PCs) [30]. Above the glass transition temperature of around 67° C., it shows quasiordered phase transition with the twist of thaiophene ring. The melting point is about 238° C. (according to MSDS, Sigma Aldrich). Crystallization temperature ranges from 80 to 128° C. depending upon thermal history, cooling or heating rate and time [31-32]. Due to such complex correlations and large variation of published results, glass transition and crystallization process was further studied using differential scanning calorimeter, correlating to the imprint thermal process conditions.

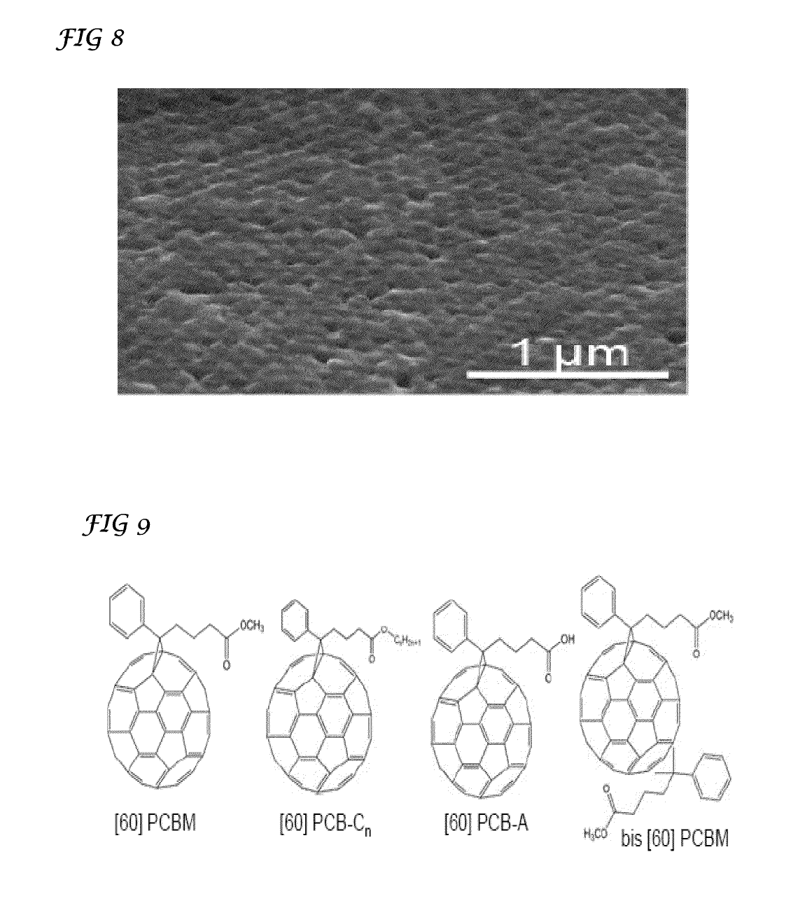

The physical and mechanical properties of P3HT polymer are also important factors in designing the nanoimprint processes. The maximum pattern thickness and stability of high-aspect ratio nanostructures depend on the Young's modulus of the film and pattern geometry. The polymer rigidity in return can be tuned by the nanoimprint process, inducing variation in crystallinity of the film. As shown in FIG. 8, the high crystallinity in P3HT resulted from nanoimprint has greatly improved its stability, allowing 700 nm tall 80 nm wide pillars to be made in comparison to collapse or clustering of similar PMMA structures of 400 nm in height (not shown). These P3HT nanostructures appear rigid compared to polymers like PMMA and polystyrene. In addition, the geometry will affect the structural stability as well; nanogratings and nanopores will be more stable than nanopillars. Each of these factors can be adjusted to achieve optimal device thickness and performance.

Nanoimprint Lithography (NIL) is not only a practical way to define heterojunction nano-morphology, but it was found to, surprisingly, create a high crystallinity, high carrier mobility, maximum absorption, and high PCE aligned polymer. Nanoimprint is a thermal process in a confined nanoscale cavity where pure polymer material is shaped into nanostructures. Annealing provides a significant improvement on crystallinity and overall PCE in blend BHJ [33]; the effects of nanoimprint on materials would be significant and also quite different from the annealing for blend BHJ due to extra nanoscale physical confinement and the purity of the used material.

Once the high-density of nanostructures are patterned on P3HT, a thin layer of electron transport material, e.g. PCBM, is deposited on top without dissolving the P3HT structures underneath. The complete filling of PCBM into the spacing area between P3HT nanostructures is important to achieve good heterojunction interface for high PCE. Both spin coating and vacuum evaporation are the general thin film deposition techniques. Spincoating or spincasting is favorable due to its fast process time and low cost. It is widely used in blend BHJ since PCBM and P3HT are mixed in the same solvents such as toluene, chlorobenzene, chloroform, dichlorobenzene. This compatibility is the key requirement for the high efficiency in bilayer, blend organic SCs. However, these compatible PCBM solvent will dissolve the P3HT nanostructures during spincoating.

Successful filling of PCBM into the nanostructured P3HT can be achieved by: 1) find excellent incompatible or orthogonal solvents for PCBM and P3HT; 2) modify molecular structure of PCBM for better solubility to enhance PCBM solution flow into the P3HT nanocavities; 3) modify molecular structure of PCBM to achieve low glass transition temperature to facilitate pure PCBM flow into the P3HT nanocavities under applied pressure and heat, without the use of solvent.

The present invention identifies incompatible solvents for use with P3HT and PCBM materials to achieve good deposition of PCBM into P3HT nanostructures using spincoating or spin-casting. Hildebrand solubility parameters (HSP)[34] are used to determine the solubility of materials in various solvents. HSP can be calculated as the square root of cohesive energy density. The cohesive energy density (C) and HSP is given by the following expression [35]:

$$C = \frac{Δ H - RT}{{V}_{m}} ; HSP = \sqrt{\frac{Δ H - RT}{{V}_{m}}} ,$$

where ΔH=heat of vaporization, R=gas constant, T=temperature, Vₘ=molar volume. If two materials have similar cohesive energy density or intermolecular interaction forces, they are miscible. Cohesive energy density and HSP can be estimated from the surface energy of the polymer, which can be determined using two-liquid contact angle measurements. This method identifies the right solvents for PCBM, which will not dissolve P3HT. The HSP of the incompatible solvents should match the HSP of the PCBM, but not that of P3HT. For solvent not to dissolve P3HT, their HSPs should differ by >2.045 (MPa)^{1/2[}36]. For instance, HSP of chlorobenzene, toluene, and dichloromethane (DCM) are 19.6, 18.2, 20.3 (MPa)^{1/2} respectively, while the HSP of P3HT and C60 are 18.6 [37] and 20.45 (MPa)^{1/2[}38-39]. Therefore, the present invention used DCM as the incompatible solvent for PCBM spincoating. 1 wt % of PCBM was dissolved in DCM without dissolving hardly any of the P3HT. FIG. 8 shows the surface of 40 nm tall P3HT pillars after PCBM deposition.

The dissolution of PCBM and its charge mobility strongly depend on the chemical structure of the material. Therefore, in addition to the solvent, modification of PCBM molecular structure can provide even more flexibility to achieve optimal deposition and higher electron current. PCBM is modified with various terminal groups. FIG. 9 shows some examples of modified PCBM that were used [40-42]. For example, the solubility of PCB-Cn increases with increase of n. PCB-C4 has 4 carbon chain while PCBM has just one which has a wider solubility window so that more solvents will be available for this compounds than PCBM. Similarly the glass transition temperature drastically reduces with the number of carbon atoms in the side chain. The glass transition temperature of PCBM is 256° C. while that of PCB-C4 is 153° C. PCB-C12 will be used for reversal nanoimprinting at room temperature for conformal filling of nanostructure geometries of P3HT. This modified PCBM provides better conductivity which will bring extra benefits to the SCs[40].

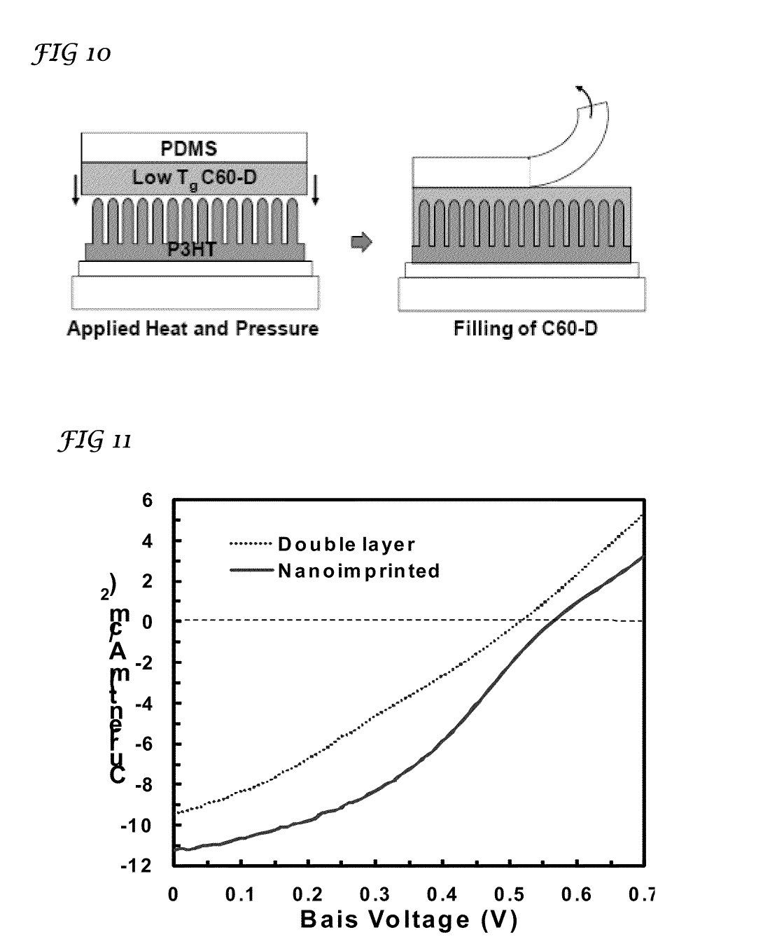

An alternative method to spincoating/casting to fill PCBM into P3HT nanocavities is described in the present invention. This technique allows transfer of material from a nanoimprint mold or a flat surface to another patterned surface with high fidelity under applied pressure and temperature. The key to this process is precise control of the surface energy of the nanoimprint mold to be high enough for spincoating of material but low enough for transferring the material to a patterned substrate (FIG. 10). Here, a PDMS transfer pad is proposed instead of a solid glass mold used previously to further facilitate PCBM filling and also for better control of PDMS release. First, PDMS was oxidized using O₂ plasma to generate a high surface energy of ˜60 mJ/m² and then PCBM solution was spincoated on the PDMS. PDMS oxidation effect lasts about one hour and after which it will return to its original low surface energy state (˜22 mJ/m²). Then the PCBM coated PDMS was brought into contact with P3HT nanostructures with pressure and temperature applied to allow PCBM to flow into the P3HT, followed by rapidly releasing PDMS off of the stack. The imprint temperature was controlled to be lower than the T_{g} of P3HT backbone (>120° C.) but higher than T_{g} of PCBM so that PCBM can flow but P3HT will not distort. For this method to succeed, the T_{g} of the PCBM must be at least 30 degrees lower than the T_{g} of P3HT.

Photovoltaic devices were completed after deposition of electrode materials. Devices of varying dimensions and geometry, were processed at varying nanoimprint temperature and characterized to understand the fundamental effects of precisely engineered nano-interface on device performance. For example, 10-20 nm PEDOT:PSS was used between P3HT and ITO to enhance hole transport. O₂ exposure was minimized during the process by conducting material processing in glove box. LiF and Aluminum were used as cathode material. Characterization was performed in a nitrogen filled glove box using a Air Mass 1.5 G solar simulated light (AMG1.5). Light absorption spectrum and coefficiency were measured using ellipsometry and light transmission tools. I-V curves of the devices were measured; fill factor, photocurrent, output voltage, and charge mobility were derived to study the correlations between nanoimprint process, resulting polymer properties, and device performance.

The results of the fabrication process are shown in Table 1 and the graph showing the current v/s voltage profile is shown in FIG. 11. A device made of only 40 nm tall and 80 nm wide P3HT pillar arrays shows a J_{sc} of 11.3 mA/cm², 40% fill factor (FF), and 2.6% PCE, which are much better than non-patterned bilayer control devices.

TABLE 1
Characteristics of a solar cell with 40 nm tall and 80 nm wide pillars.

| Parameters | Bilayer | Nanoimprinted |
|---|---|---|
| V_{oc} (V) | 0.52 | 0.57 |
| J_{sc} (mA/cm²) | 9.4 | 11.3 |
| Fill factor (FF) | 0.29 | 0.40 |
| Efficiency η (%) | 1.44 | 2.57 |

Nanoscale dimensions and geometry play a central role in determination of the solar cell performance. Organic solar cells require a much thinner active layer for energy conversion due to short exciton diffusion and high absorption coefficient of the organic materials, compared to their inorganic counterparts (few microns thick). Most research in this field uses 40-100 nm thick films as a result of considering both high internal quantum efficiency (15% IQE) and also moderate light absorption (typically EQE <25%). The proposed SC design of the present invention enabled by nanoimprinting decouples the absorption depth from the diffusion length, thereby allowing a thicker active layer to be used for high absorption without reducing exciton diffusion, which happens perpendicular to the active layer thickness. Moreover, the nanoimprint-induced high crystallinity will provide high carrier mobility, better light absorption, and larger J_{sc}.

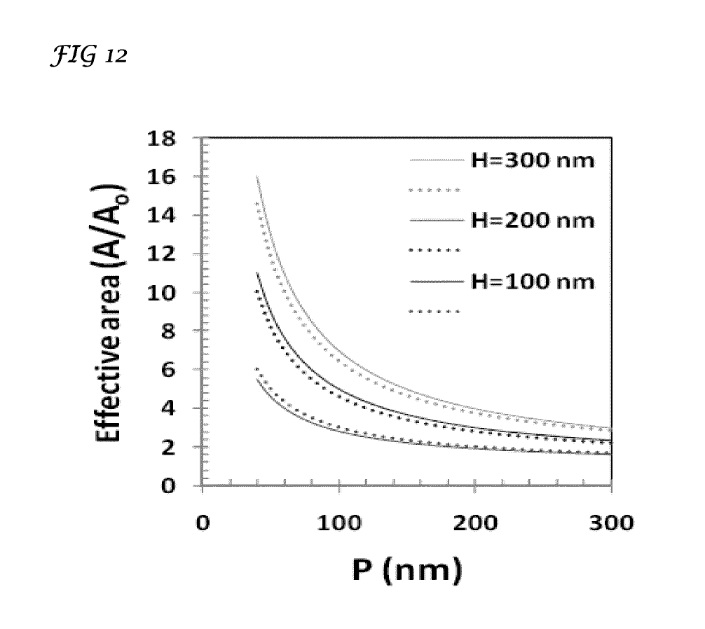

The effective interface area ratio or A/Aₒ (effective interface area over unit device area) was used to quantify the geometry effects of the SC heterojunctions. A/Aₒ for nanogratings and nanopore/pillar structures are given respectively by:

$$\frac{A}{{A}_{o}} = \frac{2 \cdot h}{P} + 1 , and \frac{A}{{A}_{o}} = ( \frac{2 π \cdot D \cdot h}{\sqrt{3} \cdot {P}^{2}} + 1 )$$

Where D is pillar/pore diameter, h and P are the height and pitch respectively for pillar/pore and grating. A/Aₒ of the heterojunction for pillar, pore and grating structures is plotted as functions of pattern pitch and height using the above equation (FIG. 12). The analysis suggests that the pitch and height are most important to increase the effective area ratio, and therefore the efficiency of the solar cells.

FIG. 11 is a plot of the current v/s voltage of a fabricated solar cell device with 40 nm tall and 80 nm wide pillars. Nanostructured polymer morphology results in improved fill factor (FF) or the efficiency of the device. FIG. 11 shows that once pitch is close to 100 nm, the area ratio beings to increase dramatically. For example when P=100 nm, 300 nm pillars/gratings will provide a 6.2 fold increase in interface area and 700 nm tall pillars offer an even greater increase of 12.7, demonstrating huge potential for PCE improvement. The area ratio of preliminary SCs shown in FIG. 10 is about 1.7, but already have a 2.6% PCE compared to 1.4% PCE of the bilayer SCs of area ratio of 1. In addition, the same A/Aₒ can be achieved by different structures. For instance ˜6.0 A/Aₒ can be obtained with 40 nm pitch and 100 nm tall or with 100 nm pitch and 250 nm tall structures. From the fabrication perspective, it would be easier to choose the latter strategy. Although the modeling studies [4] suggest 20 nm width and 40 nm pitch provides best internal quantum efficiency or IQE (80%), these dimensions will likely not give the best device performance due to the aforementioned practical issues to be considered. Simulations in other materials suggest the fill factor and J_{sc} reach the highest at the 50 nm width, not 20 nm [43]. Previous studies also showed that 50-80 nm wide P3HT structures gave the best hole mobility (20 times higher than that of 20 nm) in anodic alumina pores [44]. A pitch of 80-100 nm and structure of 20-80 nm (FIG. 7) were used to study the dimensional effects.

Charge mobility is one of the most important factors affecting the device PCE, which is exponentially related to the extent of polymer structural/morphology disorder [45]. Controlling polymer crystallinity and morphology is vital for obtaining high charge-carrier mobility [46-49]. Most studies focused on annealing of the BHJ film at varying temperature or modifying the surface of the substrate with self-assembled monolayers (SAMS), shedding some light on temperature and surface induced crystallization behaviors of the functional polymer and leading to improvement of crystallinity and light absorption [33, 50]. However, little is known about the physical nano-cavity induced crystallization and chain alignment behaviors.

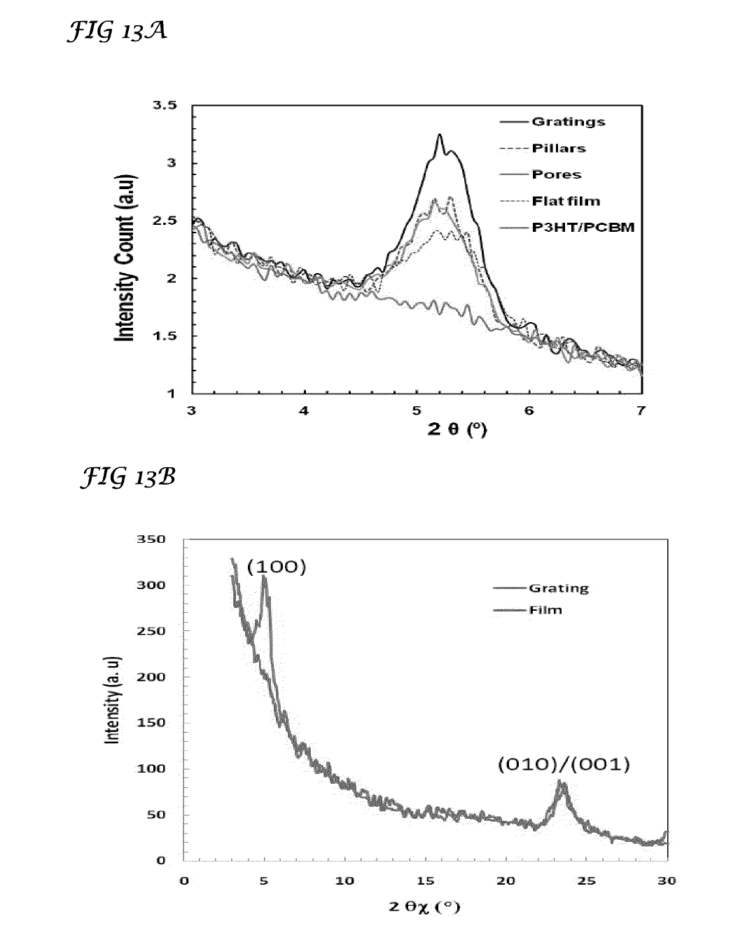

Accurate assessment of the geometry-dependent crystallinity and chain alignment requires precision metrology at nanoscale. X-ray diffraction (XRD) or grazing incidence X-ray scattering (GIXS) and high resolution TEM (HRTEM) are popular and useful metrology techniques for studying polymer crystallinity and chain alignment. The stark differences in crystallinity were determined differences between the imprinted structure and flat samples are shown in FIG. 13. As shown in Table 2 below, the crystallinity and crystal size was calculated by the established method in literature using the XRD peak height, area/width, and incidence angle and X-ray wavelength. [33, 50] Spincoated P3HT-PCBM blend and flat pure P3HT film show very low a(100) crystallinity, while nanogratings and nanopores show much higher crystallinity. The lower crystallinity in blend BHJ is expected since PCBM seams to suppress the formation of polymer nanocrystals in P3HT[33, 50] This shows that imprinting on pure P3HT material (without PCBM) does produce higher crystallinity. The nano-crystal size in imprinted samples is calculated as 16.3-18.3 nm, which is much larger than reported literature in fully optimized blend BHJ systems (8-12 nm). There is also significant difference in crystallinity between grating and pillar/pore geometry, indicating crystallization behaviors and chain alignment of P3HT does strongly depend on nanoscale geometry.

TABLE 2
Crystallinity calculation of the molded polymer nanostructures in
comparison to non-molded flat and blended polymer materials from the
XRD measurement results.

| | | Peak | Peak | | | Crystal- |
|---|---|---|---|---|---|---|
| | d | height | area | FWHM | crystallite | linity |
| sample | (nm) | (a.u) | (a.u.) | (°) | size (nm) | (a.u) |
| P3HT-PCBM | | | | | 5.3-12.2 | |
| [ref XX] | | | | | | |
| P3HT-PCBM | | | | | | |
| mixture | | | | | | |
| flat (no | 1.666 | 522 | 6355 | 0.532 | 14.9 | 6 |
| anenaling) | | | | | | |
| P3HT grating | 1.682 | 1203 | 12047 | 0.434 | 18.3 | 12 |
| (annealing) | | | | | | |
| P3HT grating | 1.697 | 1371 | 15320 | 0.478 | 16.6 | 15 |
| (170° C.) | | | | | | |
| P3HT pillars | 1.667 | 934 | 9552 | 0.447 | 17.8 | 10 |
| (170° C.) | | | | | | |
| P3HT pores | 1.712 | 840 | 9462 | 0.487 | 16.3 | 9 |
| (170° C.) | | | | | | |

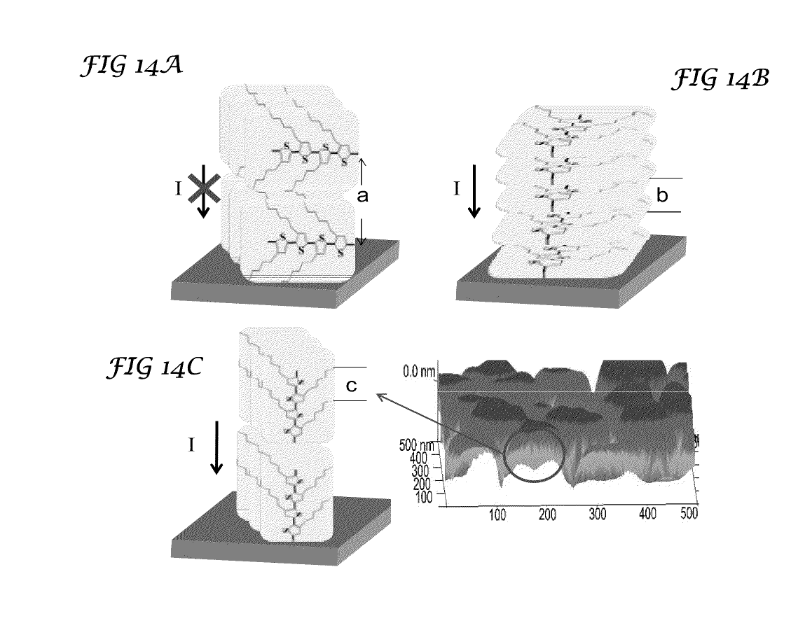

Overall crystallinity is important but not enough, since the conductivity of crystalline P3HT is anisotropically limited in two directions b(010) and c(001) while the direction of hexyl side chain a(100) is insulating, as shown in FIG. 14. The preferred orientation of P3HT for solar cell application where charge transport is perpendicular to the substrate or the surface is either π-staking direction b(010) or c(001). Heating the active layer of the device to a temperature greater than the glass temperature Tg of P3HT allows the polymer chains to reorder in a more thermodynamically favorable way [51]. Moreover, it is evident that the P3HT polymer chain tends to (may need to induce) orient parallel to the substrate [10, 52-53]. Recently Gwennaelle et al. showed the crystallization and orientation of P3HT polymer chain by nano-rubbing using velvet cloth on the stylus of an AFM to study the transport properties [54]. Nano-rubbing makes the polymer chains to orient along the rubbing direction and the mobility is higher in this direction. The transport direction of the organic solar cells is normal to the surface so the ordering of polymer chain parallel to the substrate with the nano-rubbing technique is not useful in bilayer devices and not possible in nanostructured SCs. However, the flow of polymer in the porous Si mold while nanoimprinting is very similar in nature to the nano-rubbing and hence induces possible ordering of polymer lamellae along the vertical wall of the porous mold or c(100) given the fact that the height of pillar is the longest dimension compared to lateral dimensions. Hu et al have shown recently that nanoimprint lithography (NIL) can induce the polymer chain alignment parallel to the vertical wall of the trenches for OLED [55].

Grazing incidence in-plane X-Ray diffraction or GIXRD was performed on the molded P3HT gratings and the results compared to the un-molded material. The results as shown in FIG. 13B show that the presence of (100) peak in nanogratings indicate the molded P3HT gratings have a vertical chain alignment or vertical π stacking, which are favorable polymer chain configuration for high charge mobility and high current leading to better device efficiency.

Using NIL it was found that polymer chains were able to align the polymers into inu-molecular stacks. This surprising results was confirmed as follows. Multiple metrologies, e.g. AFM, XRD, HRTEM with in-situ XRD were used to investigate the P3HT chain orientation. Both in-plane and out-plane XRD were performed and the crystalline alignment can be assessed by evaluating the ratio of (010) and/or (001) peak at 23° over the (100) peak at 5.4°. High resolution TEM was used to image P3HT chain orientation of the nanoimprinted patterns with and without PCBM. AFM was also used to provide evidence of this alignment, as shown FIG. 13; confirming a vertical fiber like texture appearing uniformly along the 40 nm tall 80 nm wide pillars. The physical confinement, the surface in contact with P3HT [46-49], and temperature may all have significant effects on the P3HT crystallinity and chain orientation. The measured crystalline orientation was correlated to light absorption coefficiency and hole mobility derived from device characteristics associated with these samples. It was found that the surprising chain alignment obtained by the present invention, considerably improved hole mobility, light absorption, and further contribute to higher SC PCE in conjunction with the optimized nano-morphology. The improved crystallinity and chain alignment greatly improved device efficiency from about 0.8% for current devices to about 3%.

In summary, photovoltaic devices or solar cells based on nanostructured charge-transfer materials and methods for their manufacturing are disclosed. These nanostructures over large areas were formed by an imprinting process or molding process using electrochemically made porous templates and their derivative molds in Si or other materials. The integration of the two-step anodization process to make the templates, template transfer and replication in other materials, polymer molding process, and the SC architectures provides allow-cost and highly efficient power generation devices that have high economical potential.

It is contemplated that any embodiment discussed in this specification can be implemented with respect to any method, kit, reagent, or composition of the invention, and vice versa. It will be understood that particular embodiments described herein are shown by way of illustration and not as limitations of the invention. The principal features of this invention can be employed in various embodiments without departing from the scope of the invention. Those skilled in the art will recognize, or be able to ascertain using no more than routine experimentation, numerous equivalents to the specific procedures described herein. Such equivalents are considered to be within the scope of this invention and are covered by the claims.

All publications and patent applications mentioned in the specification are indicative of the level of skill of those skilled in the art to which this invention pertains. All publications and patent applications are herein incorporated by reference to the same extent as if each individual publication or patent application was specifically and individually indicated to be incorporated by reference.

The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or the alternatives are mutually exclusive, although the disclosure supports a definition that refers to only alternatives and “and/or.” Throughout this application, the term “about” is used to indicate that a value includes the inherent variation of error for the device, the method being employed to determine the value, or the variation that exists among the study subjects.

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, MB, BBC, AAABCCCC, CBBAAA, CABABB, and so forth. The skilled artisan will understand that typically there is no limit on the number of items or terms in any combination, unless otherwise apparent from the context.

All of the compositions and/or methods disclosed and claimed herein can be made and executed without undue experimentation in light of the present disclosure. While the compositions and methods of this invention have been described in terms of preferred embodiments, it will be apparent to those of skill in the art that variations may be applied to the compositions and/or methods and in the steps or in the sequence of steps of the method described herein without departing from the concept, spirit and scope of the invention. All such similar substitutes and modifications apparent to those skilled in the art are deemed to be within the spirit, scope and concept of the invention as defined by the appended claims.

### REFERENCES

1. U.S. Pat. No. 5,772,905.
2. H. Hoppe and N. S. Sariciftci, “Morphology of polymer/fullerene bulk heterojunction solar cells,” Journal of Materials Chemistry, vol. 16, pp. 45-61, 2006.
3. M. S. Kim, J. S. Kim, J. C. Cho, M. Shtein, L. J. Guo, and J. Kim, “Flexible conjugated polymer photovoltaic cells with controlled heterojunctions fabricated using nanoimprint lithography,” Applied Physics Letters, vol. 90, pp.-, Mar. 19, 2007.
4. P. K. Watkins, A. B. Walker, and G. L. B. Verschoor, “Dynamical Monte Carlo modelling of organic solar cells: The dependence of internal quantum efficiency on morphology,” Nano Letters, vol. 5, pp. 1814-1818, September 2005.
5. G. Li, V. Shrotriya, J. S. Huang, Y. Yao, T. Moriarty, K. Emery, and Y. Yang, “High-efficiency solution processable polymer photovoltaic cells by self-organization of polymer blends,” Nature Materials, vol. 4, pp. 864-868, November 2005.
6. W. L. Ma, C. Y. Yang, X. Gong, K. Lee, and A. J. Heeger, “Thermally stable, efficient polymer solar cells with nanoscale control of the interpenetrating network morphology,” Advanced Functional Materials, vol. 15, pp. 1617-1622, October 2005.
7. M. Reyes-Reyes, K. Kim, and D. L. Carroll, “High-efficiency photovoltaic devices based on annealed poly(3-hexylthiophene) and 1-(3-methoxycarbonyl)-propyl-1-phenyl-(6,6)C-61 blends,” Applied Physics Letters, vol. 87, pp.-, Aug. 22, 2005.
8. L. A. A. Pettersson, L. S. Roman, and O. Inganas, “Modeling photocurrent action spectra of photovoltaic devices based on organic thin films,” Journal of Applied Physics, vol. 86, pp. 487-496, Jul. 1, 1999.
9. S. R. Scully and M. D. McGehee, “Effects of optical interference and energy transfer on exciton diffusion length measurements in organic semiconductors,” Journal of Applied Physics, vol. 100, pp.-, Aug. 1, 2006.
10. Z. Bao, A. Dodabalapur, and A. J. Lovinger, “Soluble and processable regioregular poly(3-hexylthiophene) for thin film field-effect transistor applications with high mobility,” Applied Physics Letters, vol. 69, pp. 4108-4110, Dec. 23, 1996.
11. G. Dennler and N. S. Sariciftci, “Flexible conjugated polymer-based plastic solar cells: From basics to applications,” Proceedings of the IEEE, vol. 93, pp. 1429-1439, August 2005.
12. J. J. M. Halls, C. A. Walsh, N. C. Greenham, E. A. Marseglia, R. H. Friend, S. C. Moratti, and A. B. Holmes, “Efficient Photodiodes from Interpenetrating Polymer Networks,” Nature, vol. 376, pp. 498-500, Aug. 10, 1995.
13. H. Hoppe and N. S. Sariciftci, “Organic solar cells: An overview,” Journal of Materials Research, vol. 19, pp. 1924-1945, July 2004.
14. N. S. Sariciftci, D. Braun, C. Zhang, V. I. Srdanov, A. J. Heeger, G. Stucky, and F. Wudl, “Semiconducting Polymer-Buckminsterfullerene Heterojunctions—Diodes, Photodiodes, and Photovoltaic Cells,” Applied Physics Letters, vol. 62, pp. 585-587, Feb. 8, 1993.
15. N. S. Sariciftci, L. Smilowitz, A. J. Heeger, and F. Wudl, “Photoinduced Electron-Transfer from a Conducting Polymer to Buckminsterfullerene,” Science, vol. 258, pp. 1474-1476, Nov. 27, 1992.
16. G. Yu, J. Gao, J. C. Hummelen, F. Wudl, and A. J. Heeger, “Polymer Photovoltaic Cells—Enhanced Efficiencies Via a Network of Internal Donor-Acceptor Heterojunctions,” Science, vol. 270, pp. 1789-1791, Dec. 15, 1995.
17. G. Yu and A. J. Heeger, “Charge Separation and Photovoltaic Conversion in Polymer Composites with Internal Donor-Acceptor Heterojunctions,” Journal of Applied Physics, vol. 78, pp. 4510-4515, Oct. 1, 1995.
18. S. Y. Chou, P. R. Krauss, and P. J. Renstrom, “Imprint of Sub-25 Nm Vias and Trenches in Polymers,” Applied Physics Letters, vol. 67, pp. 3114-3116, Nov. 20, 1995.
19. S. H. Ahn, J. S. Kim, and L. J. Guo, “Bilayer metal wire-grid polarizer fabricated by roll-to-roll nanoimprint lithography on flexible plastic substrate,” Journal of Vacuum Science & Technology B, vol. 25, pp. 2388-2391, November 2007.
20. D. J. Resnick, W. J. Dauksher, D. Mancini, K. J. Nordquist, T. C. Bailey, S. Johnson, N. Stacey, J. G. Ekerdt, C. G. Willson, S. V. Sreenivasan, and N. Schumaker, “Imprint lithography for integrated circuit fabrication,” Journal of Vacuum Science & Technology B, vol. 21, pp. 2624-2631, November-December 2003.
21. U.S. Patent Application No 20040096389.
22. U.S. Pat. No. 6,946,597.
23. Sang Bok Lee, et al., Antibody-Based Bio-Nanotube Membranes for Enantiomeric Drug Separations, SCIENCE, 21 Jun. 2002: Vol. 296. no. 5576, pp. 2198-2200; Kshama B. Jirage, et al., Nanotubule-Based Molecular-Filtration Membranes, SCIENCE, 24 Oct. 1997: Vol. 278. no. 5338, pp. 655-658.
24. U.S. Pat. No. 7,267,859.
25. U.S. Patent Application No. 20070165217.
26. U.S. Pat. No. 6,709,513.
27. B. Cui, Z. N. Yu, H. X. Ge, and S. Y. Chou, “Large area 50 nm period grating by multiple nanoimprint lithography and spatial frequency doubling,” Applied Physics Letters, vol. 90, pp.-, Jan. 22, 2007.
28. Z. N. Yu, W. Wu, L. Chen, and S. Y. Chou, “Fabrication of large area 100 nm pitch grating by spatial frequency doubling and nanoimprint lithography for subwavelength optical applications,” Journal of Vacuum Science & Technology B, vol. 19, pp. 2816-2819, November-December 2001.
29. Z. N. Yu, W. Wu, G. Y. Jung, D. L. Olynick, J. Straznicky, X. M. Li, Z. Y. Li, W. M. Tong, J. A. Liddle, S. Y. Wang, and R. S. Williams, “Fabrication of 30 nm pitch imprint moulds by frequency doubling for nanowire arrays,” Nanotechnology, vol. 17, pp. 4956-4961, Oct. 14, 2006.
30. K. Yazawa, Y. Inoue, T. Yamamoto, and N. Asakawa, “Twist glass transition in regioregulated poly(3-alkylthiophene),” Physical Review B, vol. 74, pp.-, September 2006.
31. C. Yang, F. P. Orfino, and S. Holdcroft, “A phenomenological model for predicting thermochromism of regioregular and nonregioregular poly(3-alkylthiophenes),” Macromolecules, vol. 29, pp. 6510-6517, Sep. 23, 1996.
32. Y. Zhao, G. X. Yuan, P. Roche, and M. Leclerc, “A Calorimetric Study of the Phase-Transitions in Poly(3-Hexylthiophene),” Polymer, vol. 36, pp. 2211-2214, May 1995.
33. U. Zhokhavets, T. Erb, G. Gobsch, M. Al-Ibrahim, and O. Ambacher, “Relation between absorption and crystallinity of poly(3-hexylthiophene)/fullerene films for plastic solar cells,” Chemical Physics Letters, vol. 418, pp. 347-350, Feb. 6, 2006.
34. J. H. Hildebrand, The Solubility of Non-Electrolytes New York: Reinhold, 1936.
35. J. Burke, Solubility Parameters: Theory and application vol. 3: The Book and Paper Group, The American Institute for Conversion 1984.
36. L. H. Sperling, Introduction to Physical Polymer Science: John Wiley & Sons: New York, 2001.
37. A. Zen, M. Saphiannikova, D. Neher, U. Asawapirom, and U. Scherf, “Comparative study of the field-effect mobility of a copolymer and a binary blend based on poly(3-alkylthiophene)s,” Chemistry of Materials, vol. 17, pp. 781-786, Feb. 22, 2005.
38. S. Rait, S. Kashyap, P. K. Bhatnagar, P. C. Mathur, S. K. Sengupta, and J. Kumar, “Effect of a buffer layer, composition and annealing on the performance of a bulk heterojunction polythiophene/fullerene composite photovoltaic device,” Physica E-Low-Dimensional Systems & Nanostructures, vol. 39, pp. 191-197, September 2007.
39. R. S. Ruoff, D. S. Tse, R. Malhotra, and D. C. Lorents, “Solubility of C-60 in a Variety of Solvents,” Journal of Physical Chemistry, vol. 97, pp. 3379-3383, Apr. 1, 1993.
40. X. Y. Deng, L. P. Zheng, C. H. Yang, Y. F. Li, G. Yu, and Y. Cao, “Polymer photovoltaic devices fabricated with blend MEHPPV and organic small molecules,” Journal of Physical Chemistry B, vol. 108, pp. 3451-3456, Mar. 18, 2004.
41. www.solennesv.com.
42. L. P. Zheng, Q. M. Zhou, X. Y. Deng, M. Yuan, G. Yu, and Y. Cao, “Methanofullerenes used as electron acceptors in polymer photovoltaic devices,” Journal of Physical Chemistry B, vol. 108, pp. 11921-11926, Aug. 12, 2004.
43. C. M. Martin, V. M. Burlakov, H. E. Assender, and D. A. R. Barkhouse, “A numerical model for explaining the role of the interface morphology in composite solar cells,” Journal of Applied Physics, vol. 102, pp.-, Nov. 15, 2007.
44. K. M. Coakley, B. S. Srinivasan, J. M. Ziebarth, C. Goh, Y. X. Liu, and M. D. McGehee, “Enhanced hole mobility in regioregular polythiophene infiltrated in straight nanopores,” Advanced Functional Materials, vol. 15, pp. 1927-1932, December 2005.
45. C. Brabec, V. Dyakonov, J. Parisi, and N. S. Sariciftci, Organic photovoltaics: Springer, 2003.
46. D. H. Kim, Y. D. Park, Y. S. Jang, H. C. Yang, Y. H. Kim, J. I. Han, D. G. Moon, S. J. Park, T. Y. Chang, C. W. Chang, M. K. Joo, C. Y. Ryu, and K. W. Cho, “Enhancement of field-effect mobility due to surface-mediated molecular ordering in regioregular polythiophene thin film transistors,” Advanced Functional Materials, vol. 15, pp. 77-82, January 2005.
47. H. Sirringhaus, P. J. Brown, R. H. Friend, M. M. Nielsen, K. Bechgaard, B. M. W. Langeveld-Voss, A. J. H. Spiering, R. A. J. Janssen, E. W. Meijer, P. Herwig, and D. M. de Leeuw, “Two-dimensional charge transport in self-organized, high-mobility conjugated polymers,” Nature, vol. 401, pp. 685-688, Oct. 14, 1999.
48. H. Sirringhaus, N. Tessler, and R. H. Friend, “Integrated optoelectronic devices based on conjugated polymers,” Science, vol. 280, pp. 1741-1744, Jun. 12, 1998.
49. P. Vanlaeke, A. Swinnen, I. Haeldermans, G. Vanhoyland, T. Aernouts, D. Cheyns, C. Deibel, J. D'Haen, P. Heremans, J. Poortmans, and J. V. Manca, “P3HT/PCBM bulk heterojunction solar cells: Relation between morphology and electro-optical characteristics,” Solar Energy Materials and Solar Cells, vol. 90, pp. 2150-2158, Sep. 6, 2006.
50. T. Erb, U. Zhokhavets, G. Gobsch, S. Raleva, B. Stuhn, P. Schilinsky, C. Waldauf, and C. J. Brabec, “Correlation between structural and optical properties of composite polymer/fullerene films for organic solar cells,” Advanced Functional Materials, vol. 15, pp. 1193-1196, July 2005.
51. Y. Kim, S. A. Choulis, J. Nelson, D. D. C. Bradley, S. Cook, and J. R. Durrant, “Device annealing effect in organic solar cells with blends of regioregular poly(3-hexylthiophene) and soluble fullerene,” Applied Physics Letters, vol. 86, pp.-, Feb. 7, 2005.
52. M. Brinkmann, D. Aldakov, and F. Chandezon, “Fabrication of oriented and periodic hybrid nanostructures of regioregular poly(3-hexylthiophene) and CdSe nanocrystals by directional epitaxial solidification,” Advanced Materials, vol. 19, pp. 3819-+, Nov. 19, 2007.
53. M. Brinkmann and J. C. Wittmann, “Orientation of regioregular poly(3-hexylthiophene) by directional solidification: A simple method to reveal the semicrystalline structure of a conjugated polymer,” Advanced Materials, vol. 18, pp. 860-+, Apr. 4, 2006.
54. G. Derue, S. Gabriele, F. Monteverde, S. Coppee, P. Damman, M. Surin, V. Geskin, P. Leclere, and R. Lazzaroni, “Structuration of Semiconducting Polymer Thin Films by Nanorubbing,” in IEEE Industrial Electronics, IECON 2006-32nd Annual Conference on, 2006, pp. 4882-4887.
55. Z. J. Hu, G. Baralia, V. Bayot, J. F. Gohy, and A. M. Jonas, “Nanoscale control of polymer crystallization by nanoimprint lithography,” Nano Letters, vol. 5, pp. 1738-1743, September 2005.

What is claimed is:

1. An optoelectronic device, comprising:
a first substrate, wherein the substrate comprises one or more active regions;
a first electrode disposed on the first substrate;
a first interdigitating, nano-structured charge-transfer molded material comprising a first electron affinity disposed on the first electrode;
a second interdigitating, nano-structured charge-transfer material comprising a second electron affinity disposed on the first interdigitating, nano-structured charge-transfer material;
a second electrode disposed in the second interdigitating, nano-structured charge-transfer material; and
a second substrate disposed on the second electrode.

2. The device of claim 1, wherein the first and second materials comprise an electron-acceptor:hole-acceptor pair.

3. The device of claim 1, wherein the first and second polymers are selected from poly(para-phenylenevinylene) derivatives, such as poly[2-methoxy-5-(2′-ethyl-hexyloxy)-1,4-phenylene vinylene] (MEH-PPV) or (poly-[2-(3,7-dimethyl-octyloxy)-5-methyloxy]-PPV (MDMO-PPV), poly(para-phenylenevinylene) (PPV), PPV copolymers, poly(thiophene) and derivatives, regioregular poly(3-octylthiophene-2,5,-diyl), regiorandom poly(3-octylthiophene-2,5,-diyl), poly (3-hexylthiophene)(P3HT), regioregular poly(3-hexylthiophene-2,5-diyl), regiorandom poly(3-hexylthiophene-2,5-diyl), poly(thienylenevinylene) and derivatives thereof, poly(isothianaphthene) and derivatives thereof, tetra-hydrothiophene precursors and derivatives thereof, organometallic polymers, polymers containing perylene units, poly(squaraines) and their derivatives, discotic liquid crystals, polyfluorenes, polyfluorene copolymers, polyfluorene-based copolymers and blends co-polymerized and/or blended with charge transporting and/or light absorbing compounds, tri-phenyl-amines and derivatives, fused thiophene rings and derivatives, and hetero-atom ring compounds with or without substituents, polymer systems with low bandgap, such as poly[2,6-(4,4-bis-(2-ethylhexyl)-4H-cyclopenta[2,1-b; 3,4-b′]-dithiophene)-alt-4,7-(2,1,3-benzothiadiazole)] PCPDTBT, quantum dots such as CdSe, Ag, Au nanoparticles, and C60 derivatives, such as 1-(3-methoxycarbonyl) propyl-1-phenyl [6,6] C61) system (PCBM), a pigment or dye chosen from the group of organic pigments or dyes, azo-dyes having azo chromofores (—N═N—) linking aromatic groups, phthalocyanines including metal-free phthalocyanine (HPc), perylenes, naphthalocyanines, squaraines, merocyanines and their respective derivatives, poly (silanes), poly(germinates), 2,9-di(pent-3-yl)-anthra[2,1,9-def: 6,5,10-d′e′f′] diisoquinoline-1,3,8,10-tetrone, and 2,9-Bis-(1-hexyl-hept-1-yl)-anthra[2,1,9-def:6,5,10-d′e′f′] diisoquinoline-1,3,8,10-tetrone, metal oxide gels, TiO₂ gel, and combinations thereof.

4. The device of claim 1, wherein at least one of the first and second substrate is optically translucent.

5. The device of claim 1, wherein the first, the second or both the first and second substrate comprise silicon, polysilicon, glass, plastic, or metal.

6. The device of claim 1, wherein the first or the second electrode comprise indium-tin-oxide (ITO) or carbon nanotubes sheets and contact the polymer layer that comprises a hole-transfer layer.

7. The device of claim 1, wherein the first or the second electrode comprise aluminum or a metal and contact the material that comprises the electron-transfer layer.

8. The device of claim 1, wherein the first and second interdigitating nano-structured charge-transfer materials comprise periodic structured nanoposts or nanopores having an average pore diameter of 10-100 nm, or nanogratings comprising a width of 10-100 nm.

9. The device of claim 1, wherein the first and second interdigitating nano-structured charge-transfer materials comprise periodic nanostructures that are separated by 1, 2, 3, 4, 5, 7, 10, 15, 20, 30, 40, 50, 60, 70, 80, 90, 100, 150, 200, 250 or 500 nm and incremental variations thereof on center.

10. The device of claim 1, wherein the first and second interdigitating nano-structured charge-transfer material comprise periodic structured nanoposts, nanopores, gratings, etc having an aspect ratio of greater than 1.

11. The device of claim 1, wherein the first and second interdigitating nano-structured charge-transfer materials comprise periodic nanostructures have a height of 1, 2, 5, 7, 10, 10, 20, 40, 50, 75, 100, 250, 500, 1,000, 2,000, 3,000, 4,000 and 5000 nm.

12. The device of claim 1, wherein the first and second interdigitating nano-structured charge-transfer materials are defined further as comprising imprint-induced nano-crystallization polymers which results in higher charge mobility, and higher power output.

13. The device of claim 1, further comprising one or more passivation layers on the first or second substrates opposite the first and second electrodes.

14. The device of claim 1, further comprising one or more extra electron and hole injection material to be used between the nanostructured materials and electrodes to enhance charge transport and collection at electrodes.

15. The device of claim 1, further comprising one or more functional materials selected from PEDOT:PSS/Sorbitol (Poly(3,4-ethylenedioxythiophene) poly(styrenesulfonate) and quantum dots, CdSe particles, Au particles, Ag particles, wherein the functional material is deposited between the interdigitating nanostructured hole and electron transfer materials to enhance light absorption and charge generation.

16. An optoelectronic device, comprising:
a first substrate, wherein the substrate comprises one or more active regions;
an electrode disposed on the first substrate;
a first interdigitating, nano-structured charge-transfer molded materials comprising a first electron affinity disposed on the first electrode, wherein the first nano-structured polymer comprises aligned or stacked molecules or polymer chains;
a second interdigitating, nano-structured charge-transfer material comprising a second electron affinity disposed on the first interdigitating, nano-structured charge-transfer polymer, wherein the second nano-structured polymer comprises aligned or stacked molecules or chains; and
a second electrode disposed in the second interdigitating, nano-structured charge-transfer material; and a layer disposed on the second electrode.

17. The device of claim 16, wherein at least one of the first and second aligned or stacked polymer chains are further defined as comprising vertical chain aligned polymer nanopillars or gratings.

18. The device of claim 16, wherein at least one of the first and second aligned or stacked polymer chains comprise laterally aligned and vertically stacked “π-chains”, π stacking vertically in the pillars or gratings.

19. The device of claim 16, wherein the crystallinity of molded material is greater than the crystallinity of un-molded material.

20. A method of making an optoelectronic device, comprising:
nanoimprinting or molding a first interdigitating, nano-structured charge-transfer material with a template mold on a substrate, wherein the substrate comprises one or more active regions, the material comprising a base and one or more nanoposts, nanopores, or nanogratings; depositing a second charge-transfer material layer on the first interdigitating, nano-structured charge-transfer materials to form a electron-acceptor:hole-acceptor polymer pair; and
connecting each of the first and second nano-structured charge-transfer material to an electrode, wherein at least one of the electrodes in translucent.

21. The method of claim 20, wherein at least one of the first and second substrate is optically translucent.

22. The method of claim 20, wherein the first and second interdigitating nano-structured charge-transfer materials are defined further as comprising aligned imprint-induced nano-crystallization polymers, resulting in higher charge mobility, and higher power output.

23. The method of claim 20, wherein the one or more functional materials comprise quantum dots.

24. The method of claim 20, wherein the step of forming a first interdigitating, nano-structured charge-transfer polymer with a template mold comprises:
coating an template with a silane; and
heating, UV treating or pressurizing the charge-transfer material into nanocavities in the template.

25. The method of claim 20, wherein the second charge-transfer material is deposited on an electrode and bonded to the first charge transfer layer with a second nanoimprint process.

26. The method of claim 20, wherein the second charge-transfer material is deposited on a substrate and is interdigitated to the first charge transfer layer in a nanoimprint process.

27. The method of claim 20, wherein the charge-transfer materials comprise increased adhesion and electrical contact of the charge-transfer materials, by modifying the polymer chain ends with functional groups, changing the chemical coating of the particle surfaces, or using one or more solvents that improve material deposition.

28. A method of making a highly-ordered, nanopore template comprising:
anodizing a polished anodizable template;
dissolving the anodized template to form a pock-marked template; and
re-anodizing the pock-marked template, wherein the re-anodized template comprises a plurality of cells that comprise an anodized barrier layer and a pore

29. The method of claim 28, wherein the anodized membrane is released from the template and used a mask to etch into another material forming a derivative nanostructured template.

30. A template made by the method of claim 28.

31. A method of orienting a polymer chain in a polymer by nanoimprinting comprising the steps of:
selecting the polymer for nanoimprinting;
spreading the polymer as a layer for nanoimprinting;
adjusting a temperature of the polymer layer; wherein said temperature is above the glass transition temperature of the selected polymer;
adjusting a viscosity of the polymer layer;
contacting the polymer layer with a porous template mold, wherein said template mold comprises one or more nano-structures;
flowing the polymer into the porous mold;
releasing the porous mold from the polymer layer; and
monitoring the orientation of the polymer chains by one or more analytical techniques.

32. The method of claim 31, wherein the polymer chain is aligned vertically.

33. The method of claim 31, wherein the 7r stacking of the polymer is aligned vertically.

34. The method of claim 31, wherein the polymer for nanoimprinting is selected from poly(para-phenylenevinylene) derivatives, such as poly[2-methoxy-5-(2′-ethyl-hexyloxy)-1,4-phenylene vinylene] (MEH-PPV) or (poly-[2-(3,7-dimethyl-octyloxy)-5-methyloxy]-PPV (MDMO-PPV), poly(para-phenylenevinylene) (PPV), PPV copolymers, poly(thiophene) and derivatives, regioregular poly(3-octylthiophene-2,5,-diyl), regiorandom poly(3-octylthiophene-2,5,-diyl), poly (3-hexylthiophene)(P3HT), regioregular poly(3-hexylthiophene-2,5-diyl), regiorandom poly(3-hexylthiophene-2,5-diyl), poly(thienylenevinylene) and derivatives thereof, poly(isothianaphthene) and derivatives thereof, tetra-hydrothiophene precursors and derivatives thereof, organometallic polymers, polymers containing perylene units, poly(squaraines) and their derivatives, discotic liquid crystals, polyfluorenes, polyfluorene copolymers, polyfluorene-based copolymers and blends co-polymerized and/or blended with charge transporting and/or light absorbing compounds, tri-phenyl-amines and derivatives, fused thiophene rings and derivatives, and hetero-atom ring compounds with or without substituents, polymer systems with low bandgap, such as poly[2,6-(4,4-bis-(2-ethylhexyl)-4H-cyclopenta[2,1-b; 3,4-b′]-dithiophene)-alt-4,7-(2,1,3-benzothiadiazole)] PCPDTBT, quantum dots, and C60 derivatives, such as 1-(3-methoxycarbonyl) propyl-1-phenyl [6,6] C61) system (PCBM), a pigment or dye chosen from the group of organic pigments or dyes, azo-dyes having azo chromofores (—N═N—) linking aromatic groups, phthalocyanines including metal-free phthalocyanine (HPc), perylenes, naphthalocyanines, squaraines, merocyanines and their respective derivatives, poly (silanes), poly(germinates), 2,9-di(pent-3-yl)-anthra[2,1,9-def: 6,5,10-d′e′f′] diisoquinoline-1,3,8,10-tetrone, and 2,9-Bis-(1-hexyl-hept-1-yl)-anthra[2,1,9-def:6,5,10-d′e′f′] diisoquinoline-1,3,8,10-tetrone and combinations thereof.

35. The method of claim 31, wherein the porous template mold is selected from Si, GaAs, glass, silicon nitride, graphite, SiC, diamond, diamond like carbon, Ni, Cr, Ti, Copper, Pt, SU8, polydimethylsiloxane (PDMS), perfluoropolyether (PFPE), hydrogen silsesquioxane (HSQ), and combinations thereof.

36. The method of claim 31, wherein the mold comprises anodic metal film selected from aluminium, titanium, zinc, magnesium, niobium, or alloys thereof.

37. The method of claim 31, wherein said one or more nano-structures comprise conical, tubular and other morphologies.

38. The method of claim 31, wherein the one or more analytical techniques comprise X-ray diffraction, X-ray scattering, atomic force microscopy, high resolution tunneling electron microscopy, scanning electron microscopy and combinations thereof.

39. The method of claim 31, wherein the oriented polymer is disposed on an electrode.

40. A method of filling a patterned functional layer disposed on a surface with a charge transfer material comprising the steps of:
oxidizing a transfer surface;
spin-coating the charge transfer material on the oxidized transfer surface;
adjusting a temperature of the charge transfer material coated oxidized transfer surface; wherein the temperature of the coated charge transfer material is below the glass transition temperature of the patterned polymer layer disposed on the surface;
contacting the coated and oxidized transfer surface with the patterned polymer layer disposed on the surface;
applying heat and pressure to a stack, wherein the stack comprises the patterned polymer layer disposed on the surface and the charge transfer material coated oxidized transfer surface;
adjusting the temperature of the stack, wherein the temperature is lower than glass transition temperature of the patterned polymer layer disposed on the surface;
flowing the charge transfer material from the polymer coated oxidized transfer surface into the patterned polymer layer disposed on the surface; and
releasing the oxidized transfer surface from the stack.

41. The method of claim 40, wherein the transfer surface comprises polydimethylsiloxane or other silicon based rubber.

42. The method of claim 40, wherein the surface comprises a substrate or an electrode selected from silicon, polysilicon, glass, plastic, indium-tin-oxide (ITO) or carbon nanotubes or metal.

43. The method of claim 40, wherein the transfer surface is oxidized with an oxygen plasma.

44. The method of claim 40, wherein said method is used to deposit a charge-transfer polymer layer on a first interdigitating nano-structured polymer layer; wherein said deposition is used to fabricate an optoelectronic device or a solar cell.
